(19) United States
(12) Patent Application Publication
(10) Pub. No.: US 2023/0039473 A1
(43) Pub. Date: Feb. 9, 2023

(54) WIRING QUALITY TEST METHOD AND APPARATUS AND STORAGE MEDIUM

(71) Applicant: CHANGXIN MEMORY TECHNOLOGIES, INC., Hefei City (CN)

(72) Inventor: Tao DU, Heifei City (CN)

(73) Assignee: CHANGXIN MEMORY TECHNOLOGIES, INC., Hefei City (CN)

(21) Appl. No.: 17/936,838

(22) Filed: Sep. 29, 2022

Related U.S. Application Data
(63) Continuation of application No. PCT/CN2021/138400, filed on Dec. 15, 2021.

(30) Foreign Application Priority Data
Sep. 8, 2021 (CN) 202111049249.8

(51) Int. Cl. G06F 30/398

(52) U.S. Cl. CPC G06F 30/398

(57) ABSTRACT

A wiring quality test method includes the following: a respective wiring result topological structure and a respective expected topological structure corresponding to each signal to be tested in a set of signals to be tested are determined based on a wiring layout; for each signal to be tested, the wiring result topological structure is compared with the expected topological structure, to obtain a topological structure comparison result corresponding to the signal to be tested; in response to determining that the topological structure comparison result is greater than a preset threshold, it is determined a test result indicating that wiring for the signal to be tested is inappropriate; and a quality test report is generated based on test results of the signals to be tested.

### CROSS-REFERENCE TO RELATED APPLICATIONS

This is a continuation of International Patent Application No. PCT/CN2021/138400 filed on Dec. 15, 2021, which claims priority to Chinese Patent Application No. 202111049249.8 filed on Sep. 8, 2021. The disclosures of the above-referenced applications are hereby incorporated by reference in their entirety.

### BACKGROUND

With the continuous development of semiconductor technology, the number of electronic components in integrated circuits keeps increasing and the internal structures of the integrated circuits are becoming increasingly complex, which brings greater challenges to the design of integrated circuits.

In the development of layout-design of the integrated circuits, the wiring quality is required to be tested after the wiring design is completed. If the wiring quality is tested through manual inspection and post-simulation verification, the test time is excessively long.

### SUMMARY

The disclosure relates to the field of integrated circuit design, and the embodiments of the disclosure aim to provide a wiring quality test method and apparatus and a non-transitory computer-readable storage medium.

In a first aspect, the embodiments of the disclosure provide a wiring quality test method, which includes the following operations.

A respective wiring result topological structure and a respective expected topological structure corresponding to each signal to be tested in a set of signals to be tested are determined based on a wiring layout. The expected topological structure is obtained based on a position of at least one connection point in the wiring layout.

For each signal to be tested, the wiring result topological structure is compared with the expected topological structure, to obtain a topological structure comparison result corresponding to the signal to be tested; and in response to determining that the topological structure comparison result is greater than a preset threshold, it is determined a test result indicating that wiring for the signal to be tested is inappropriate.

A quality test report is generated based on test results of the signals to be tested.

In a second aspect, the embodiments of the disclosure further provide a wiring quality test apparatus, which includes a memory and a processor.

The memory is configured to store executable instructions.

The processor is configured to execute the executable instructions stored in the memory to perform the following operations including: determining, based on a wiring layout, a respective wiring result topological structure and a respective expected topological structure corresponding to each signal to be tested in a set of signals to be tested, wherein the expected topological structure is obtained based on a position of at least one connection point in the wiring layout; for each signal to be tested, comparing the wiring result topological structure with the expected topological structure, to obtain a topological structure comparison result corresponding to the signal to be tested; in response to determining that the topological structure comparison result is greater than a preset threshold, determining a test result indicating that wiring for the signal to be tested is inappropriate; and generating a quality test report based on test results of the signals to be tested.

In a third aspect, the embodiments of the disclosure further provide a non-transitory computer-readable storage medium, storing executable instructions that, when executed by a processor, cause the processor to perform a wiring quality test method including: determining, based on a wiring layout, a respective wiring result topological structure and a respective expected topological structure corresponding to each signal to be tested in a set of signals to be tested, wherein the expected topological structure is obtained based on a position of at least one connection point in the wiring layout; for each signal to be tested, comparing the wiring result topological structure with the expected topological structure, to obtain a topological structure comparison result corresponding to the signal to be tested; in response to determining that the topological structure comparison result is greater than a preset threshold, determining a test result indicating that wiring for the signal to be tested is inappropriate; and generating a quality test report based on test results of the signals to be tested.

### BRIEF DESCRIPTION OF THE DRAWINGS

FIG. 1 is a first flowchart of a wiring quality test method according to an embodiment of the disclosure.

FIG. 2 is an exemplary diagram of an expected topological structure according to an embodiment of the disclosure.

FIG. 3A is a first schematic diagram of obtaining an actual wiring pattern according to an embodiment of the disclosure.

FIG. 3B is a second schematic diagram of obtaining an actual wiring pattern according to an embodiment of the disclosure.

FIG. 3C is a third schematic diagram of obtaining an actual wiring pattern according to an embodiment of the disclosure.

FIG. 4A is a first schematic diagram of a type of an actual wiring pattern according to an embodiment of the disclosure.

FIG. 4B is a second schematic diagram of a type of an actual wiring pattern according to an embodiment of the disclosure.

FIG. 4C is a third schematic diagram of a type of an actual wiring pattern according to an embodiment of the disclosure.

FIG. 5 is a second flowchart of a wiring quality test method according to an embodiment of the disclosure.

FIG. 6 is an effect diagram of displaying a test result according to an embodiment of the disclosure.

FIG. 7 is a third flowchart of a wiring quality test method according to an embodiment of the disclosure.

FIG. 8 is a fourth flowchart of a wiring quality test method according to an embodiment of the disclosure.

FIG. 9 is a fifth flowchart of a wiring quality test method according to an embodiment of the disclosure.

FIG. 10 is a sixth flowchart of a wiring quality test method according to an embodiment of the disclosure.

FIG. 11 is a seventh flowchart of a wiring quality test method according to an embodiment of the disclosure.

FIG. 12 is an eighth flowchart of a wiring quality test method according to an embodiment of the disclosure.

FIG. 13 is a ninth flowchart of a wiring quality test method according to an embodiment of the disclosure.

FIG. 14 is a tenth flowchart of a wiring quality test method according to an embodiment of the disclosure.

FIG. 15 is an eleventh flowchart of a wiring quality test method according to an embodiment of the disclosure.

FIG. 16 is a twelfth flowchart of a wiring quality test method according to an embodiment of the disclosure.

FIG. 17 is a first schematic structural diagram of a wiring quality test apparatus according to an embodiment of the disclosure.

FIG. 18 is a second schematic structural diagram of a wiring quality test apparatus according to an embodiment of the disclosure.

### DETAILED DESCRIPTION

To make the objectives, technical solutions, and advantages of the disclosure clearer, the technical solutions of the disclosure are further described below in detail with reference to the accompanying drawings and the embodiments. The described embodiments should not be construed as a limitation to the disclosure. All other embodiments obtained by persons of ordinary skill in the art without creative efforts fall within the protection scope of the disclosure.

In the following description, reference is made to “some embodiments”, which describes a subset of all possible embodiments. However, it may be understood that “some embodiments” may be the same subset or different subsets of all possible embodiments, and may be combined with each other without conflict.

The following explanations will be added if the terms “first/second” and a similar description appear in the disclosure. In the following description, the terms “first/second/third” are only used to distinguish similar objects and do not denote a specific order of object. It is to be noted that the terms “first/second/third” may be interchanged in a specific order or sequence where appropriate, to enable embodiments of the disclosure described herein to be practiced in an order other than the order shown or described herein.

Unless otherwise defined, all the technical terms and scientific terms used herein have the same meanings as generally understood by a person skilled in the art to which the disclosure pertains. The terms used herein are merely used for describing the embodiments of the disclosure, but are not intended to limit the disclosure.

In the development of the layout-design of integrated circuits, a layout includes a large number of signal lines. For example, a peripheral layer of a Dynamic Random Access Memory (DRAM) chip layout includes more than 15,000 signal lines. Therefore, an automatic wiring tool is required to be used to complete the connection of a large number of signal lines (i.e., massive automatic wiring) to meet the requirements of a project deadline.

However, automatic wiring cannot completely satisfy design requirements. For example, an excessively long wiring line, an excessively long large-resistance metal wire used for a critical signal, and/or the like will lead to a failure of the corresponding signal. Therefore, after the automatic wiring is completed, the wiring quality of a layout must be tested.

In some implementations, there are only methods such as one-by-one manual inspection and post-simulation verification and the like, which have problems such as an excessively long period and difficulty in later modification.

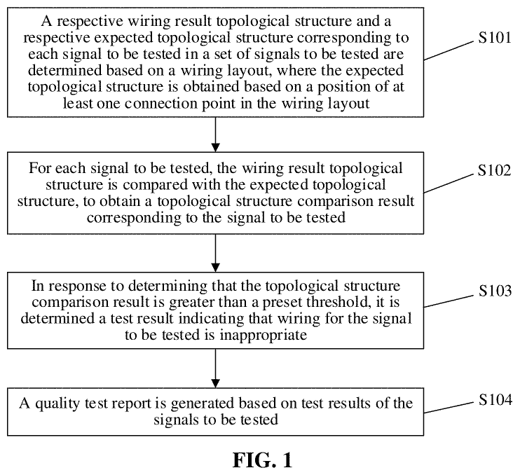

FIG. 1 is an optional schematic flowchart of a wiring quality test method according to an embodiment of the disclosure, which will be described with reference to the operations shown in FIG. 1.

In an operation S101, a respective wiring result topological structure and a respective expected topological structure corresponding to each signal to be tested in a set of signals to be tested are determined based on a wiring layout, where the expected topological structure is obtained based on a position of at least one connection point in the wiring layout.

In the embodiments of the disclosure, a wiring quality test apparatus may determine, based on the wiring layout, the respective wiring result topological structure and the respective expected topological structure corresponding to each signal to be tested in the set of signals to be tested, where the expected topological structure is obtained based on the position of the at least one connection point in the wiring layout.

It should be noted that a plurality of signals are required to be used in an integrated circuit, and each of the signals will pass through part of connection lines in the integrated circuit. Therefore, in the wiring layout, an actual wiring pattern corresponding to connection lines through which a signal to be tested passes may be determined.

In the embodiments of the disclosure, before determining the wiring result topological structure and the expected topological structure, the wiring quality test apparatus first determines at least one connection point (pin) through which the signal to be tested passes. Since it may be difficult to clearly display all connection objects and connection points through which the signal to be tested passes in the wiring layout, the wiring quality test apparatus may first obtain a wiring circuit diagram corresponding to the wiring layout and then determines at least one connection point corresponding to each signal to be tested based on the wiring layout and the wiring circuit diagram. The process may include the following operations.

In an operation 1, a connection object label is obtained in the wiring circuit diagram. The wiring quality test apparatus may first obtain at least one connection object label corresponding to each signal to be tested in the wiring circuit diagram.

It should be noted that the connection object label is a symbol of an electrical connection object in the wiring circuit diagram, which represents a module (instance) with a specific function in the circuit. Any connection object label in the wiring circuit diagram has a corresponding connection object in the wiring layout. The connection object is a pattern in the wiring layout, which represents that the module can be formed in a corresponding physical area in the chip, to implement the function of the module.

In an operation 2, a connection object is matched in the wiring layout. After obtaining the at least one connection object label, the wiring quality test apparatus may match at least one connection object corresponding to the at least one connection object label in the wiring layout.

In an operation 3, a connection point is determined in the wiring layout. After matching the at least one connection object, the wiring quality test apparatus may determine at least one connection point corresponding to each signal to be tested in the wiring layout based on the at least one connection object. It should be noted that the connection object is electrically connected by the connection point(s). Once the connection point(s) are determined, endpoints of the connection line(s) through which the signal to be tested passes are determined.

In the embodiments of the disclosure, after determining the at least one connection point corresponding to each signal to be tested, the wiring quality test apparatus may determine the respective expected topological structure and the respective wiring result topological structure corresponding to each signal to be tested in the wiring layout based on the at least one connection point. The expected topological structure reflects an expected result of layout wiring, and the wiring result topological structure reflects an actual result of the layout wiring. The expected topological structure may be used as a standard and reference for the wiring result topological structure, for guiding actual layout wiring work.

It should be noted that the topological structure in the embodiments of the disclosure is an abstract description of signal lines in a layout by using two graphical elements, namely, ‘point’ and ‘line’. The graphical element ‘point’ is used to describe the at least one connection point corresponding to each signal to be tested to specify a position of the at least one connection point in the wiring layout. The graphical element ‘line’ is used to describe at least one wiring pattern connected to the at least one connection point to specify a path and length of each signal line.

In the embodiments of the disclosure, the wiring quality test apparatus may determine expected connection lines of N levels (N is greater than or equal to 1) in a level-wise manner, to form the expected topological structure. The expected topological structure includes the at least one connection point and the expected connection lines of N levels. The process may include the following operations.

In an operation 1, intermediate base lines of N levels are determined. The wiring quality test apparatus may take the at least one connection point as at least one first-level connection point in the wiring layout; and determine two first-level edge connection points having a largest distance in a first axial direction among the at least one first-level connection point, and determine a first-level intermediate base line passing through a midpoint of a connection line between the two first-level edge connection points and in a second axial direction.

After determining the first-level intermediate base line, the wiring quality test apparatus may determine connection points having an axial distance less than a second-level preset threshold in the at least one first-level connection point as second-level connection points. The axial distance is a distance in the first axial direction or the second axial direction, and the first axial direction is perpendicular to the second axial direction. Further, the wiring quality test apparatus may determine a second-level intermediate base line based on the second-level connection points by using a method similar to that for determining the first-level intermediate base line. That is to say, the wiring quality test apparatus may determine two second-level edge connection points having a largest distance in the first axial direction among second-level connection points, and determine the second-level intermediate base line passing through a midpoint of a connection line between the two second-level edge connection points and in the second axial direction.

After determining the second-level intermediate base line, the wiring quality test apparatus may determine a third-level intermediate base line according to the similar method, and repeat such a process until an N^{th}-level intermediate base line is determined. That is to say, the wiring quality test apparatus may determine connection points having an axial distance less than an i^{th}-level preset threshold in (i-1)^{th}-level connection points as i^{th}-level connection points, where i is greater than or equal to 2 and i is less than or equal to N−1. Next, the wiring quality test apparatus determines two i^{th}-level edge connection points having a largest distance in the first axial direction among the i-level connection points, and determines an i^{th}-level intermediate base line passing through a midpoint of a connection line between the two i^{th}-level edge connection points and in the second axial direction. Further, the wiring quality test apparatus continues to determine (i+1)^{th}-level connection points and an (i+1)^{th}-level intermediate base line until N^{th}-level connection points and an N^{th}-level intermediate base line are determined, thereby determining the intermediate base lines of N levels.

In an operation 2, expected connection lines of N levels are determined. The wiring quality test apparatus may determine an expected connection line of each level based on connection points of each level and an intermediate base line of each level in the connection points of N levels and the intermediate base lines of N levels, thereby determining the expected connection lines of N levels.

For a first connection point that does not satisfy a preset distance condition in the connection points of each level in the connection points of N levels, the wiring quality test apparatus may connect the first connection point of each level to the intermediate base line of the level corresponding to the first connection point to form a perpendicular segment, so as to obtain a first sub-expected connection line corresponding to the first connection point. The preset distance condition corresponding to the connection points of each level is that the axial distance is less than a next-level preset threshold. For a second connection point that satisfies the preset distance condition in the connection points of each level in the connection points of N levels, the wiring quality test apparatus may connect the intermediate base line of each level corresponding to the second connection point of the level to the intermediate base line of a next level to form a common perpendicular segment, so as to obtain a second sub-expected connection line corresponding to the second connection point. The first sub-expected connection line and the second sub-expected connection line are taken as the expected connection line of each level. Until the connection points of N levels have been connected, the expected connection lines of N levels may be determined.

In another aspect, in some embodiments of the disclosure, after determining the intermediate base lines of N levels, the wiring quality test apparatus may first determine an N^{th}-level expected connection line based on the N^{th}-level connection points and the N^{th}-level intermediate base line, and then determine a previous-level expected connection line level by level, to eventually determine a first-level expected connection line. That is to say, the wiring quality test apparatus may determine a j^{th}-level expected connection line based on a j^{th}-level connection point, a j^{th}-level intermediate base line, and a (j+1)^{th}-level expected connection line, where j is greater than or equal to 2, and j is less than or equal to N−1. Next, the wiring quality test apparatus continues to determine a (j−1)^{th}-level expected connection line until the first-level expected connection line is determined, thereby determining the expected connection lines of N levels.

The wiring quality test apparatus may first determine the N^{th}-level expected connection line based on the N^{th}-level connection points and the N^{th}-level intermediate base line. The wiring quality test apparatus may construct, based on the N^{th}-level connection points, perpendicular segments of each group of N^{th}-level connection points to the corresponding N^{th}-level intermediate base line, to obtain N^{th}-level connection point connection lines. The each group of N^{th}-level connection points are connection points, axial distances between any two of which are all less than an N^{th}-level preset threshold. Next, perpendicular foots of the N^{th}-level connection point connection lines on the corresponding N^{th}-level intermediate base line are connected to obtain at least one N^{th}-level base line connection line, thereby obtaining the N^{th}-level expected connection line including the N^{th}-level connection point connection lines and the at least one N^{th}-level base line connection line.

After determining the N^{th}-level expected connection line, the wiring quality test apparatus may construct perpendicular segments of each group of (N−1)^{th}-level connection points to the corresponding (N−1)^{th}-level intermediate base line and at least one common perpendicular segment of the at least one N^{th}-level base line connection line to the corresponding (N−1)^{th}-level intermediate base line, to obtain (N−1)^{th}-level connection point connection lines. The each group of (N−1)^{th}-level connection points are connection points, axial distances between any two of which are all less than an (N−1)^{th}-level preset threshold. Next, perpendicular foots of the (N−1)^{th}-level connection point connection lines on the corresponding (N−1)^{th}-level intermediate base line are connected to obtain at least one (N−1)^{th}-level base line connection line, thereby obtaining an (N−1)^{th}-level expected connection line including the (N−1)^{th}-level connection point connection lines and the at least one (N−1)^{th}-level base line connection line. The resting is deduced by analogy in sequence according to the process until the first-level expected connection line is determined. That is to say, the wiring quality test apparatus may construct perpendicular segments of each group of j^{th}-level connection points to the corresponding j^{th}-level intermediate base line and at least one common perpendicular segment of at least one (j+1)^{th}-level base line connection line to the corresponding j^{th}-level intermediate base line, to obtain j^{th}-level connection point connection lines. The each group of j^{th}-level connection points are connection points, axial distances between any two of which are all less than a j^{th}-level preset threshold. Next, perpendicular foots of the j^{th}-level connection point connection lines on the corresponding j^{th}-level intermediate base line are connected to obtain at least one j^{th}-level base line connection line, thereby obtaining the j^{th}-level expected connection line including the j^{th}-level connection point connection lines and the at least one j^{th}-level base line connection line.

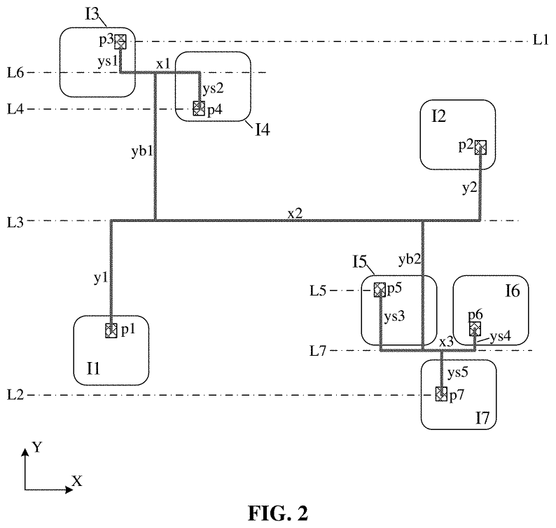

In some embodiments of the disclosure, N=2. FIG. 2 is an optional exemplary diagram of an expected topological structure according to an embodiment of the disclosure. As shown in FIG. 2, at least one connection point includes connection points p1, p2, p3, p4, p5, p6, and p7, which correspond to connection objects I1, I2, I3, I4, I5, I6, and I7, respectively. The wiring quality test apparatus may first determine all the connection points p1, p2, p3, p4, p5, p6, and p7 as first-level connection points, and then determines two first-level edge connection points p3 and p7 having the largest distance in a Y-axis direction among the first-level connection points. First-level edge lines L1 and L2 extend in an X-axis direction to pass through p3 and p7 respectively, which characterizes positions of p3 and p7 in the Y-axis direction. The wiring quality test apparatus may determine a first-level intermediate base line L3 based on the positions of p3 and p7 in the Y-axis direction. L3 is a middle parallel line of L1 and L2, and L3 has equal distances from L1 and L2.

With continued reference to FIG. 2, after the first-level intermediate base line L3 is determined, the wiring quality test apparatus may determine second-level connection points having an axial distance less than a second-level preset threshold among the first-level connection points p1, p2, p3, p4, p5, p6, and p7. For example, if the second-level preset threshold is 150 and axial distances between p3 and p4 in the X-axis direction and the Y-axis direction are both less than 150, then p3 and p4 are determined as a group of second-level connection points; if axial distances between any two of p5, p6, and p7 in the X-axis direction and the Y-axis direction are both less than 150, then p5, p6, and p7 are determined as another group of second-level connection points. That is to say, each group of second-level connection points is within a 150×150 range.

With continued reference to FIG. 2, after determining each group of second-level connection points, the wiring quality test apparatus may determine a respective second-level intermediate base line corresponding to each group of second-level connection points. For example, for the group of second-level connection points including p3 and p4, the wiring quality test apparatus first determines two second-level edge connection points having the largest distance in the Y-axis direction. Because the group of second-level connection points has only two members, the two members are directly taken as the second-level edge connection points. Corresponding second-level edge lines L1 and L4 extend in the X-axis direction (L1 is also a first-level edge line) to pass through p3 and p4 respectively, which characterizes positions of p3 and p4 in the Y-axis direction. The wiring quality test apparatus may determine a second-level intermediate base line L6 corresponding to the group of second-level connection points based on the positions of p3 and p4 in the Y-axis direction. L6 is a middle parallel line of L1 and L4, and L6 has equal distances from L1 and L4. For another example, for the another group of second-level connection points including p5, p6, and p7, the wiring quality test apparatus first determines two second-level edge connection points p5 and p7 having the largest distance in the Y-axis direction. Corresponding second-level edge lines L5 and L2 extend in the X-axis direction (L2 is also a first-level edge line) to pass through p5 and p7 respectively, which characterizes positions of p5 and p7 in the Y-axis direction. The wiring quality test apparatus may determine a second-level intermediate base line L7 corresponding to the another group of second-level connection points based on the positions of p5 and p7 in the Y-axis direction. L7 is a middle parallel line of L5 and L2, and L7 has equal distances from L5 and L2.

With continued reference to FIG. 2, after the first-level intermediate base line and the second-level intermediate base line are determined, the wiring quality test apparatus may construct perpendicular segments of connection points of each level to the corresponding intermediate base line of the level. That is to say, the wiring quality test apparatus constructs perpendicular segments y1 and y2 of p1 and p2 to L3, respectively; constructs perpendicular segments ys1 and ys2 of p3 and p4 to L6, respectively; and constructs perpendicular segments ys3, ys4, and ys5 of p5, p6, and p7 to L7, respectively. Moreover, the wiring quality test apparatus may construct common perpendicular segments yb1 and yb2 of the second-level intermediate base lines L6 and L7 to the first-level intermediate base line L3, respectively. Then, the wiring quality test apparatus may connect perpendicular foots of all perpendicular segments and common perpendicular segments on the intermediate base line of each level. That is to say, the wiring quality test apparatus connects perpendicular foots of ys1 and ys2 on L6 to obtain x1; connects perpendicular foots of y1, y2, yb1, and yb2 on L3 to obtain x2; and connects perpendicular foots of ys3, ys4, and ys5 on L7 to obtain x3. In this way, an expected topological structure formed by the connection points pl, p2, p3, p4, p5, p6, and p7 and the line segments x1, x2, x3, y1, y2, ys1, ys2, ys3, ys4, and ys5 is obtained.

In the embodiments of the disclosure, the wiring quality test apparatus may determine at least one actual wiring pattern connected to the at least one connection point in the wiring layout; and determine a type of each actual wiring pattern according to a preset classification rule, and simplify each actual wiring pattern, to obtain at least one actual connection line corresponding to the at least one actual wiring pattern, thereby obtaining the wiring result topological structure including the at least one connection point and the at least one actual connection line.

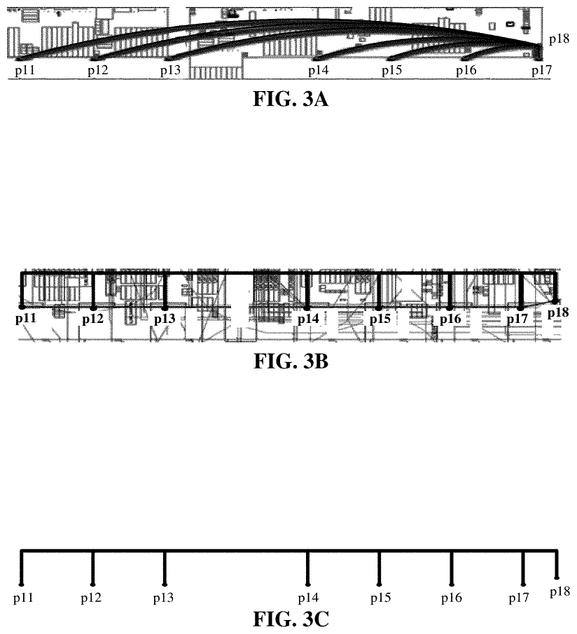

FIG. 3A, FIG. 3B, and FIG. 3C exemplify a process of obtaining an actual wiring pattern, which is described with reference to the drawings. As shown in FIG. 3A, the wiring quality test apparatus may determine connection points p11, p12, p13, p14, p15, p16, p17, and p18 in the wiring circuit diagram. Next, as shown in FIG. 3B, the wiring quality test apparatus may determine corresponding positions of the connection points p11, p12, p13, p14, p15, p16, p17, and p18 in the wiring layout, and determine an actual wiring pattern connecting these connection points in the wiring layout. Finally, as shown in FIG. 3C, the obtained actual wiring pattern is extracted.

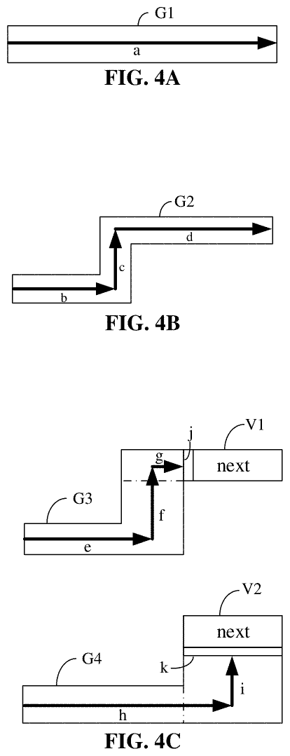

In some embodiments of the disclosure, types of actual wiring patterns include a rectangle, a path, and a polygon. FIG. 4A, FIG. 4B, and FIG. 4C exemplify the obtaining of at least one actual connection line corresponding to the actual wiring patterns of three types, respectively, which are described with reference to the drawings.

As shown in FIG. 4A, the actual wiring pattern G1 is a rectangle. The wiring quality test apparatus may take a perpendicular bisector a of a short side of the rectangle in G1 as an actual connection line corresponding to G1.

As shown in FIG. 4B, the actual wiring pattern G2 is a path. The wiring quality test apparatus may connect center points along axial directions of the path in G2 to obtain actual connection lines b, c, and d corresponding to G2.

As shown in FIG. 4C, actual wiring patterns G3 and G4 are polygons. G3 and a layer via V1 are connected at a layer via connection line j, and G4 and a layer via V2 are connected at a layer via connection line k. The layer vias V1 and V2 have a “next” label, which indicates that the layer vias V1 and V2 may be connected to a next layer of wiring. For G3, the wiring quality test apparatus may take a perpendicular bisector g of the layer via connection line j as an actual connection line corresponding to G3, and determine actual connection lines e and f according to the method corresponding to the actual wiring pattern of the path type, thereby obtaining actual connection lines e, f, and g corresponding to G3. For G4, the wiring quality test apparatus may take a perpendicular bisector i of the layer via connection line k as an actual connection line corresponding to G4, and determine an actual connection line h according to the method corresponding to the actual wiring pattern of the rectangle type, thereby obtaining actual connection lines h and i corresponding to G4.

In an operation S102, for each signal to be tested, the wiring result topological structure is compared with the expected topological structure, to obtain a topological structure comparison result corresponding to the signal to be tested.

In the embodiments of the disclosure, after obtaining the wiring result topological structure and the expected topological structure, the wiring quality test apparatus may compare the wiring result topological structure with the expected topological structure, to obtain the respective topological structure comparison result corresponding to each signal to be tested.

In the embodiments of the disclosure, the wiring quality test apparatus may calculate an expected wiring length of the expected topological structure and an actual wiring length of the wiring result topological structure, and compare the actual wiring length with the expected wiring length, to obtain the topological structure comparison result.

The expected wiring length includes a total expected wiring length, that is, a total length of all expected connection lines in the expected topological structure. The actual wiring length includes a total actual wiring length, that is, a total length of all actual connection lines in the wiring result topological structure. The wiring quality test apparatus may take a ratio of the total actual wiring length to the total expected wiring length as the topological structure comparison result. For example, Table 1 shows an example.

TABLE 1

| | Total actual wiring | Total expected wiring | |
|---|---|---|---|
| Signal name | length | length | Ratio |
| netA | 963.417 | 679.419 | 141.8% |
| netB | 5691.201 | 5169.737 | 110.1% |
| netC | 2134.079 | 944.885 | 225.9% |

The Table 1 lists total actual wiring lengths, total expected wiring lengths, and ratios of the total actual wiring lengths to the total expected wiring lengths for three signals to be tested netA, netB, and netC. The ratio of the total actual wiring length to the total expected wiring length for netA is 141.8%, the ratio of the total actual wiring length to the total expected wiring length for netB is 110.1%, and the ratio of the total actual wiring length to the total expected wiring length for netC is 225.9%.

In addition, the expected wiring length further includes at least one layer-wise expected wiring length, that is, at least one expected connection line length corresponding to at least one metal layer. The actual wiring length further includes at least one layer-wise actual wiring length, that is, at least one actual connection line length corresponding to the at least one metal layer. The wiring quality test apparatus may compare each layer-wise actual wiring length with a respective layer-wise expected wiring length at the same metal layer as the layer-wise actual wiring length to obtain at least one metal layer ratio, and take the at least one metal layer ratio as the topological structure comparison result. It should be noted that the wiring layout includes the at least one metal layer. Metal connection lines in different metal layers are located at different positions in an actual chip structure. That is, an upper layer metal connection line is located above a lower layer metal connection line.

In some embodiments of the disclosure, the at least one layer-wise expected wiring length may be a preset length corresponding to the at least one metal layer. That is, the expected connection line length may be a preset value. For example, Table 2 shows an example.

TABLE 2

| | Layer-wise actual | Layer-wise expected |
|---|---|---|
| Signal name | wiring length (Mx) | wiring length (Mx) |
| netA | — | 150 |
| netB | 615.245 | 150 |
| netC | 246.874 | 150 |

The Table 2 lists layer-wise actual wiring lengths and layer-wise expected wiring lengths for three signals to be tested netA, netB, and netC at a metal layer Mx. There is no layer-wise actual wiring length for netA at the metal layer Mx, which represents that there is no metal wiring for netA at the metal layer Mx. A layer-wise actual wiring length for netB at the metal layer Mx is 615.245. A layer-wise actual wiring length for netC at the metal layer Mx is 246.874. The layer-wise expected wiring lengths for netA, netB, and netC at the metal layer Mx are all the preset value 150.

In an operation S103, in response to determining that the topological structure comparison result is greater than a preset threshold, it is determined a test result indicating that wiring for the signal to be tested is inappropriate.

In the embodiments of the disclosure, the wiring quality test apparatus may compare the respective topological structure comparison result of each signal to be tested with the preset threshold. If the topological structure comparison result is greater than the preset threshold, it may be determined the test result indicating that the wiring for the corresponding signal to be tested is inappropriate.

In the embodiments of the disclosure, the wiring quality test apparatus may compare the ratio of the actual wiring total length to the expected wiring total length corresponding to the signal to be tested with a corresponding total length ratio preset threshold. For example, if the preset threshold is 120%, the ratios corresponding to netA and netC in Table 1 are both greater than the preset threshold, it may be determined the test results indicating that netA and netC correspond to inappropriate wiring.

In the embodiments of the disclosure, for any metal layer, the wiring quality test apparatus may compare the ratio of the layer-wise actual wiring length to the layer-wise expected wiring length with a corresponding layer-wise length ratio preset threshold. For example, if the preset threshold is 100%, the ratios corresponding to netB and netC in Table 2 are both greater than the preset threshold, it may be determined the test results indicating that netB and netC correspond to inappropriate wiring. It may be understood that the layer-wise length ratio preset threshold is set to be 100%, which represents that the layer-wise actual wiring length should not be greater than the corresponding layer-wise expected wiring length.

In an operation S104, a quality test report is generated based on test results of the signals to be tested.

In the embodiments of the disclosure, after determining a respective test result of each signal to be tested, the wiring quality test apparatus may generate the quality test report based on the test results of the signals to be tested. The quality test report may include a respective topological structure comparison result and respective wiring position information corresponding to each signal to be tested. The wiring position information is used for displaying the actual wiring pattern corresponding to the signal to be tested on the wiring layout, and may be coordinate information of connection point(s).

It may be understood that the wiring quality test apparatus obtains the wiring result topological structure and the expected topological structure and then perform comparison and judgment to determine inappropriate wiring. In this way, results of automatic wiring are tested by running procedures without search and verification one by one by designers, so that the test of wiring quality is quickly completed, thereby implementing the automatic test of wiring quality and saving the test time. Therefore, it is convenient for the designers to modify and improve automatic wiring later, thereby shortening the development cycle of a chip.

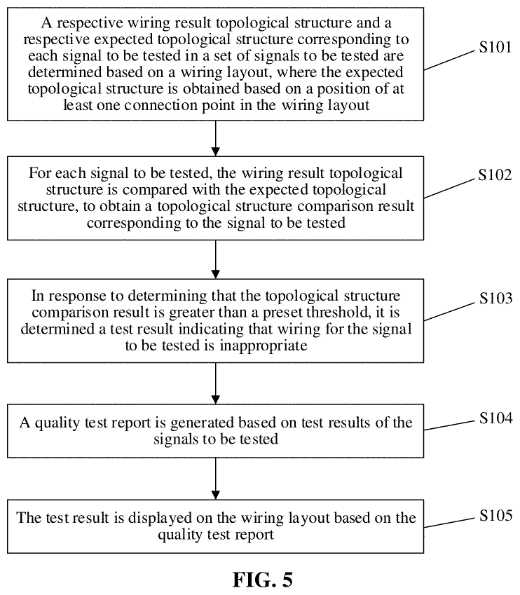

In some embodiments of the disclosure, after the operation S104 shown in FIG. 1, the method further includes an operation S105 shown in FIG. 5, which will be described with reference to the operations.

In the operation S105, the test result is displayed on the wiring layout based on the quality test report.

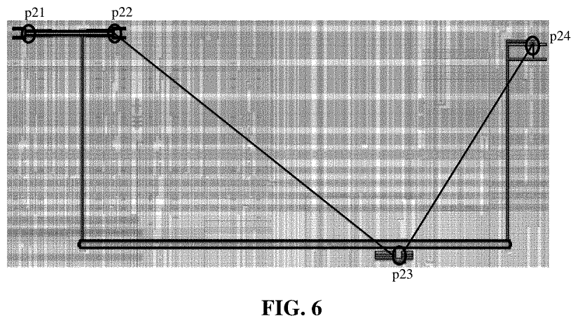

In the embodiments of the disclosure, the wiring quality test apparatus may display the test result on the wiring layout based on the quality test report, to assist the designers in viewing and locating inappropriate wiring. After launching the wiring layout, the designers may read the quality test report, and select a signal to be displayed that the designers intend to view from the set of signals to be tested. The wiring quality test apparatus may receive a selection operation for the set of signals to be tested, determine the signal to be displayed, and determine a test result corresponding to the signal to be displayed based on the quality test report. If the test result indicates that wiring for the signal to be displayed is inappropriate, the wiring quality test apparatus may emphasize the inappropriate wiring on the wiring layout. For example, the inappropriate wiring is highlighted, as shown in FIG. 6, the wiring quality test apparatus highlights inappropriate wiring passing through connection points p21, p22, p23, and p24 on the wiring layout. Direct connection lines between p21, p22, p23, and p24 are not actual wiring, but instead are used for assisting the designers in locating the positions of connection point(s). In this way, the display of the test result on the wiring layout is completed.

In the embodiments of the disclosure, after inappropriate wiring for a signal to be tested is displayed on the wiring layout, the designers may modify the inappropriate wiring. After the modification is completed, the designers click on the signal to be tested in the set of signals to be tested again, and the wiring quality test apparatus repeats the foregoing wiring quality test method for the signal to be tested to obtain a test result corresponding to the signal to be tested. If the test result indicates that there is no inappropriate wiring, the wiring quality test apparatus pops up a “Succeed” prompt on a viewing interface, and cancels highlighting for the signal to be tested. If the test result indicates that there is still inappropriate wiring, the wiring quality test apparatus pops up inappropriate item information of the test result on the viewing interface, and highlights the inappropriate wiring for the signal to be tested again, to prompt the designers to continue to make modification. Such a process is repeated until there is no more inappropriate wiring in the test results of all the signals to be tested.

It should be noted that the modification of inappropriate wiring can be completed by automatic wiring. This is not limited herein.

It may be understood that the wiring quality test apparatus highlights inappropriate wiring on the wiring layout, which can assist the designers in modifying and improving the inappropriate wiring, thereby optimizing actual wiring into an optimal solution.

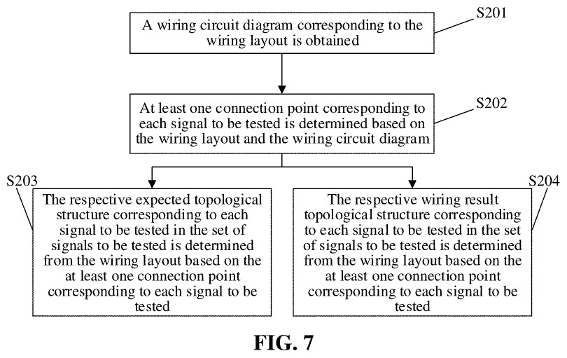

In some embodiments of the disclosure, the operation S101 shown in FIG. 1 may be implemented through operations S201 to S204 shown in FIG. 7, which will be described with reference to the operations.

In an operation S201, a wiring circuit diagram corresponding to the wiring layout is obtained.

In the embodiments of the disclosure, it may be difficult to clearly display all connection objects and connection points through which the signal to be tested passes in the wiring layout, therefore, the wiring quality test apparatus may first obtain the wiring circuit diagram corresponding to the wiring layout.

In an operation S202, at least one connection point corresponding to each signal to be tested is determined based on the wiring layout and the wiring circuit diagram.

In the embodiments of the disclosure, after obtaining the wiring circuit diagram, the wiring quality test apparatus may determine the at least one connection point corresponding to each signal to be tested based on the wiring layout and the wiring circuit diagram. The wiring quality test apparatus may first obtain connection object label(s) in the wiring circuit diagram, and then match connection object(s) and determine connection point(s), in the wiring layout.

In an operation S203, the respective expected topological structure corresponding to each signal to be tested in the set of signals to be tested is determined from the wiring layout based on the at least one connection point corresponding to each signal to be tested.

In the embodiments of the disclosure, after determining the at least one connection point corresponding to each signal to be tested, the wiring quality test apparatus may determine the respective expected topological structure corresponding to each signal to be tested from the wiring layout based on the at least one connection point. The wiring quality test apparatus may determine expected connection lines of N levels (N is greater than or equal to 1) level-by-level, to form the expected topological structure.

In an operation S204, the respective wiring result topological structure corresponding to each signal to be tested in the set of signals to be tested is determined from the wiring layout based on the at least one connection point corresponding to each signal to be tested.

In the embodiments of the disclosure, after determining the at least one connection point corresponding to each signal to be tested, the wiring quality test apparatus may further determine the respective wiring result topological structure corresponding to each signal to be tested from the wiring layout based on the at least one connection point. The wiring quality test apparatus may first determine at least one actual wiring pattern connected to the at least one connection point in the wiring layout; and simplify each actual wiring pattern based on a type of the actual wiring pattern to obtain at least one actual connection line corresponding to the at least one actual wiring pattern, thereby forming the wiring result topological structure.

It may be understood that the wiring quality test apparatus first determines the position of at least one connection point through which connection line(s) passes in the wiring layout, and then obtains the wiring result topological structure and the expected topological structure based on the at least one connection point. In this way, the obtained expected topological structure can better satisfy an actual situation, and is more accurate as a comparison object of the wiring result topological structure, so that inappropriate wiring can be determined more accurately.

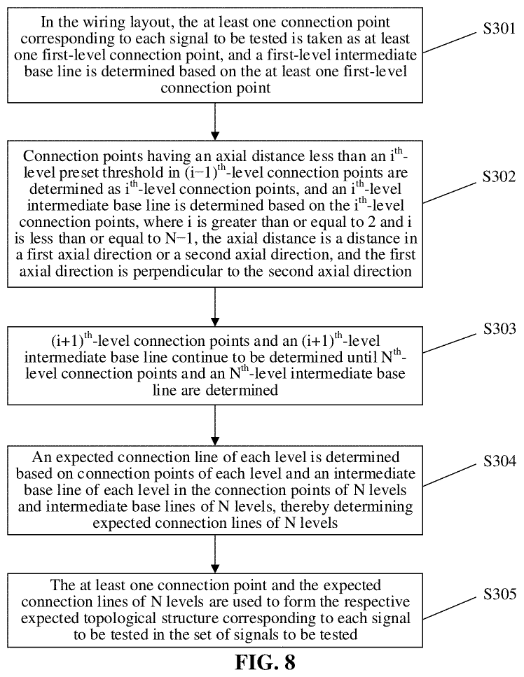

In some embodiments of the disclosure, the at least one connection point includes connection points of N levels, where N is greater than or equal to 1. The operation S203 shown in FIG. 7 may be implemented through operations S301 to S305 shown in FIG. 8, which will be described with reference to the operations.

In an operation S301, in the wiring layout, the at least one connection point corresponding to each signal to be tested is taken as at least one first-level connection point, and a first-level intermediate base line is determined based on the at least one first-level connection point.

In the embodiments of the disclosure, the wiring quality test apparatus may first take the at least one connection point as the at least one first-level connection point in the wiring layout, and determine the first-level intermediate base line based on the at least one first-level connection point.

In an operation S302, connection points having an axial distance less than an i^{th}-level preset threshold in (i−1)^{th}-level connection points are determined as i^{th}-level connection points, and an i^{th}-level intermediate base line is determined based on the i^{th}-level connection points, where i is greater than or equal to 2 and i is less than or equal to N−1, the axial distance is a distance in a first axial direction or a second axial direction, and the first axial direction is perpendicular to the second axial direction.

In the embodiments of the disclosure, starting from determining the second-level intermediate base line, the wiring quality test apparatus may determine the connection points having the axial distance less than the i^{th}-level preset threshold in the (i−1)^{th}-level connection points as the i^{th}-level connection points, and determine the i^{th}-level intermediate base line based on the i^{th}-level connection points, where i is greater than or equal to 2 and i is less than or equal to N−1, the axial distance is the distance in the first axial direction or the second axial direction, and the first axial direction is perpendicular to the second axial direction.

In an operation S303, (i+1)^{th}-level connection points and an (i+1)^{th}-level intermediate base line continue to be determined until N^{th}-level connection points and an N^{th}-level intermediate base line are determined.

In the embodiments of the disclosure, the wiring quality test apparatus may continue to determine the (i+1)^{th}-level connection points and the (i+1)^{th}-level intermediate base line until the N^{th}-level connection points and the N^{th}-level intermediate base line are determined. In this way, the connection points of N levels and the intermediate base lines of N levels are obtained.

In an operation S304, an expected connection line of each level is determined based on connection points of each level and an intermediate base line of each level in the connection points of N levels and intermediate base lines of N levels, thereby determining expected connection lines of N levels.

In the embodiments of the disclosure, the wiring quality test apparatus may determine the expected connection line of each level based on the connection points of each level and the intermediate base line of each level in the connection points of N levels and the intermediate base lines of N levels, thereby determining the expected connection lines of N levels.

In an operation S305, the at least one connection point and the expected connection lines of N levels are used to form the respective expected topological structure corresponding to each signal to be tested in the set of signals to be tested.

In the embodiments of the disclosure, the wiring quality test apparatus may use the at least one connection point and the expected connection lines of N levels to form the respective expected topological structure corresponding to each signal to be tested in the set of signals to be tested.

It may be understood that the wiring quality test apparatus divides all connection points into different levels based on axial distances between the connection points to determine the expected connection lines of N levels level-by-level, so that a total length of the expected connection lines can be reduced. In addition, the determined expected connection lines better conform to the design habits in actual wiring, so that inappropriate wiring can be determined more accurately.

In some embodiments of the disclosure, the operation S304 shown in FIG. 8 may be implemented through operations S3041 to S3043, which will be described with reference to operations.

In an operation S3041, an N^{th}-level expected connection line is determined based on the N^{th}-level connection points and the N^{th}-level intermediate base line.

In the embodiments of the disclosure, after determining the connection points of N levels and the intermediate base lines of N levels, the wiring quality test apparatus may first determine the N^{th}-level expected connection line based on the N^{th}-level connection points and the N^{th}-level intermediate base line.

In an operation S3042, a j^{th}-level expected connection line is determined based on j^{th}-level connection points, a j^{th}-level intermediate base line, and a (j+1)^{th}-level expected connection line, where j is greater than or equal to 2 and j is less than or equal to N−1.

In the embodiments of the disclosure, starting from the (N−1)^{th}-level expected connection line, the wiring quality test apparatus may determine the j^{th}-level expected connection line based on the j^{th}-level connection points, the j^{th}-level intermediate base line, and the (j+1)^{th}-level expected connection line, where j is greater than or equal to 2 and j is less than or equal to N−1.

In an operation S3043, a (j−1)^{th}-level expected connection line continues to be determined until a first-level expected connection line is determined, thereby determining the expected connection lines of N levels.

In the embodiments of the disclosure, the wiring quality test apparatus may continue to determine the (j−1)^{th}-level expected connection line until the first-level expected connection line is determined, thereby determining the expected connection lines of N levels.

It may be understood that the wiring quality test apparatus may first determine the N^{th}-level expected connection line, and then determine a previous-level expected connection line level by level in reverse order, until the first-level expected connection line is determined, thereby completing the determination of the expected connection lines of N levels. Since the expected connection line includes inter-baseline connection line from the intermediate base line of each level to the previous-level intermediate base line, the determination in reverse order can effectively ensure that the inter-baseline connection line is not missed.

In some embodiments of the disclosure, the operation S301 shown in FIG. 8 may be implemented through operations S3011 and S3012, which will be described with reference to operations.

In an operation S3011, two first-level edge connection points having a largest distance in the first axial direction among the at least one first-level connection point are determined.

In the embodiments of the disclosure, after taking the at least one connection point as the at least one first-level connection point, the wiring quality test apparatus may determine the two first-level edge connection points having the largest distance in the first axial direction among the at least one first-level connection point. In the example as shown in FIGS. 2, p3 and p7 are the two first-level edge connection points having the largest distance in the Y-axis direction (that is, the first axial direction).

In an operation S3012, the first-level intermediate base line passing through a midpoint of a connection line between the two first-level edge connection points and in the second axial direction is determined.

In the embodiments of the disclosure, after determining the two first-level edge connection points, the wiring quality test apparatus may determine the first-level intermediate base line passing through the midpoint of the connection line between the two first-level edge connection points and in the second axial direction. In the example as shown in FIG. 2, L3 is the first-level intermediate base line passing through the midpoint of the connection line between p3 and p7 and in the X-axis direction (that is, the second axial direction).

In some embodiments of the disclosure, the operation S302 shown in FIG. 8 may be implemented through operations S3021 and S3022, which will be described with reference to the operations.

In an operation S3021, two i^{t}-level edge connection points having a largest distance in the first axial direction among the i^{t}-level connection points are determined.

In the embodiments of the disclosure, starting from determining the second-level intermediate base line, the wiring quality test apparatus may determine the connection points having the axial distance less than the i^{th}-level preset threshold in the (i−1)^{th}-level connection points as the i^{th}-level connection points, and then determine the two i^{th}-level edge connection points having the largest distance in the first axial direction among the i^{th}-level connection points.

In an operation S3022, the i^{th}-level intermediate base line passing through a midpoint of a connection line between the two i^{th}-level edge connection points and in the second axial direction is determined.

In the embodiments of the disclosure, after determining the two i^{th}-level edge connection points, the wiring quality test apparatus may determine the i^{th}-level intermediate base line passing through the midpoint of the connection line between the two i^{th}-level edge connection points and in the second axial direction. In this way, the N^{th}-level intermediate base line may be determined in sequence.

In some embodiments of the disclosure, the operation S304 shown in FIG. 8 may be implemented through operations S3044 to S3046, which will be described with reference to the operations.

In an operation S3044, for a first connection point that does not satisfy a preset distance condition in the connection points of each level in the connection points of N levels, the first connection point of each level is connected to the intermediate base line of the level corresponding to the first connection point to form a perpendicular segment, so as to obtain a first sub-expected connection line corresponding to the first connection point.

In the embodiments of the disclosure, for the first connection point that does not satisfy the preset distance condition in the connection points of each level in the connection points of N levels, the wiring quality test apparatus may connect the first connection point of each level to the intermediate base line of the level corresponding to the first connection point to form the perpendicular segment, so as to obtain the first sub-expected connection line corresponding to the first connection point. The preset distance condition corresponding to the connection points of each level is that the axial distance is less than a next-level preset threshold.

In an operation S3045, for a second connection point that satisfies the preset distance condition in the connection points of each level in the connection points of N levels, the intermediate base line of each level corresponding to the second connection point of the level is connected to the intermediate base line of a next level to form a common perpendicular segment, so as to obtain a second sub-expected connection line corresponding to the second connection point. The first sub-expected connection line and the second sub-expected connection line are taken as the expected connection line of each level.

In the embodiments of the disclosure, for the second connection point that satisfies the preset distance condition in the connection points of each level in the connection points of N levels, the wiring quality test apparatus may connect the intermediate base line of each level corresponding to the second connection point of the level to the intermediate base line of a next level to form the common perpendicular segment of, so as to obtain the second sub-expected connection line corresponding to the second connection point. The first sub-expected connection line and the second sub-expected connection line are taken as the expected connection line of each level.

In an operation S3046, until the connection points of N levels have been connected, the expected connection lines of N levels are determined.

In the embodiments of the disclosure, the wiring quality test apparatus sequentially completes the foregoing process, and when the connection points of N levels have been connected, the expected connection lines of N levels may be determined.

It may be understood that the wiring quality test apparatus determines the expected connection lines of N levels level-by-level, so that a total length of the expected connection lines can be reduced. In addition, the determined expected connection lines better conform to the design habits in actual wiring, so that inappropriate wiring can be determined more accurately.

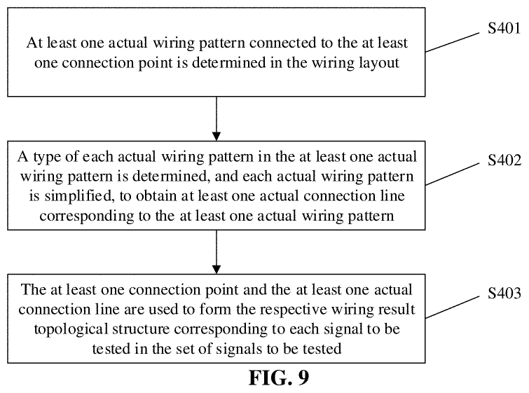

In some embodiments of the disclosure, the operation S204 shown in FIG. 7 may be implemented through operation S401 to S403 shown in FIG. 9, which will be described with reference to the operations.

In an operation S401, at least one actual wiring pattern connected to the at least one connection point is determined in the wiring layout.

In the embodiments of the disclosure, in a process of obtaining the wiring result topological structure, the wiring quality test apparatus may determine the at least one actual wiring pattern connected to the at least one connection point in the wiring layout. The actual wiring pattern represents metal line(s) electrically connecting the connection points in the layout.

In an operation S402, a type of each actual wiring pattern in the at least one actual wiring pattern is determined, and each actual wiring pattern is simplified, to obtain at least one actual connection line corresponding to the at least one actual wiring pattern.

In the embodiments of the disclosure, after determining the at least one actual wiring pattern, the wiring quality test apparatus may first determine the type of each actual wiring pattern, and then simplify each actual wiring pattern based on the type of the actual wiring pattern, thereby obtaining the at least one actual connection line corresponding to the at least one actual wiring pattern.

In an operation S403, the at least one connection point and the at least one actual connection line are used to form the respective wiring result topological structure corresponding to each signal to be tested in the set of signals to be tested.

In the embodiments of the disclosure, after obtaining the at least one actual connection line, the wiring quality test apparatus may use the at least one connection point and the at least one actual connection line to form the respective wiring result topological structure corresponding to each signal to be tested.

In some embodiments of the disclosure, the operation S402 shown in FIG. 9 may be implemented through operations S4021 and S4024, which will be described with reference to the operations.

In an operation S4021, it is determined that each actual wiring pattern is one of a rectangle, a path, and a polygon.

In the embodiments of the disclosure, types of actual wiring patterns may include a rectangle, a path, and a polygon. The wiring quality test apparatus may determine that each actual wiring pattern is one of the rectangle, the path, and the polygon.

In an operation S4022, in response to determining that the actual wiring pattern is a rectangle, a perpendicular bisector of a short side of the rectangle in the actual wiring pattern is taken as at least one actual connection line corresponding to the actual wiring pattern.

In the embodiments of the disclosure, if determining that the actual wiring pattern is the rectangle, the wiring quality test apparatus may take the perpendicular bisector of the short side of the rectangle in the actual wiring pattern as the at least one actual connection line corresponding to the actual wiring pattern. As shown in FIG. 4A, the actual wiring pattern G1 is a rectangle. The wiring quality test apparatus may take the perpendicular bisector a of the short side of the rectangle in G1 as the actual connection line corresponding to G1.

In an operation S4023, in response to determining that the actual wiring pattern is a path, center points in axial directions of the path in the actual wiring pattern are connected to form at least one actual connection line corresponding to the actual wiring pattern.

In the embodiments of the disclosure, if determining that the actual wiring pattern is the path, the wiring quality test apparatus may connect center points in the axial directions of the path in the actual wiring pattern to form the at least one actual connection line corresponding to the actual wiring pattern. As shown in FIG. 4B, the actual wiring pattern G2 is a path. The wiring quality test apparatus may connect center points in the axial directions of the path in G2 to obtain the actual connection lines b, c, and d corresponding to G2.

In an operation S4024, in response to determining that the actual wiring pattern is a polygon, which represents that the actual wiring pattern and a layer via are connected at a layer via connection line, a perpendicular bisector of the layer via connection line in the actual wiring pattern is taken as at least one actual connection line corresponding to the actual wiring pattern, thereby obtaining the at least one actual connection line corresponding to the at least one actual wiring pattern.

In the embodiments of the disclosure, if determining that the actual wiring pattern is the polygon, the wiring quality test apparatus may take the perpendicular bisector of the layer via connection line in the actual wiring pattern as the at least one actual connection line corresponding to the actual wiring pattern, thereby obtaining the at least one actual connection line corresponding to the at least one actual wiring pattern. The actual wiring pattern is the polygon, which represents that the actual wiring pattern and the layer via are connected at the layer via connection line. As shown in FIG. 4C, actual wiring patterns G3 and G4 are polygons. For G3, the wiring quality test apparatus may use the perpendicular bisector g of the layer via connection line j as the actual connection line corresponding to G3. For G4, the wiring quality test apparatus may use the perpendicular bisector i of the layer via connection line k as the actual connection line corresponding to G4.

It may be understood that the wiring quality test apparatus simplifies the actual wiring pattern based on the type of the actual wiring pattern, and the obtained actual connection line(s) better conforms to the design concept and habits of the layout wiring design, so that the electrical meaning of the layout wiring design can be reflected more accurately, thereby obtaining a more accurate wiring result topological structure.

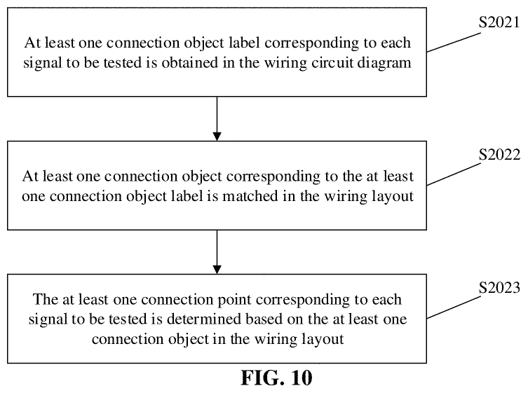

In some embodiments of the disclosure, the operation S202 shown in FIG. 7 may be implemented through operations S2021 to S2023 shown in FIG. 10, which will be described with reference to the operations.

In an operation S2021, at least one connection object label corresponding to each signal to be tested is obtained in the wiring circuit diagram.

In the embodiments of the disclosure, in a process of obtaining the at least one connection point, the wiring quality test apparatus may first obtain the at least one connection object label corresponding to each signal to be tested in the wiring circuit diagram.

It should be noted that the connection object label is a symbol of an electrical connection object in the wiring circuit diagram, which represents a module (instance) with a specific function in the circuit. Any connection object label in the wiring circuit diagram has a corresponding connection object in the wiring layout. The connection object is a pattern in the wiring layout, which represents that the module can be formed in a corresponding physical area in the chip, to implement the function of the module.

In an operation S2022, at least one connection object corresponding to the at least one connection object label is matched in the wiring layout.

In the embodiments of the disclosure, after determining the at least one connection object label, the wiring quality test apparatus may match the at least one connection object corresponding to the at least one connection object label in the wiring layout.

In an operation S2023, the at least one connection point corresponding to each signal to be tested is determined based on the at least one connection object in the wiring layout.

After matching the at least one connection object, the wiring quality test apparatus may determine the at least one connection point corresponding to each signal to be tested in the wiring layout based on the at least one connection object.

It should be noted that the connection object is electrically connected by the connection point(s). Once the connection point(s) is/are determined, endpoints of the connection line(s) through which the signal to be tested passes are determined.

It may be understood that the wiring quality test apparatus determines the at least one connection point based on the wiring circuit diagram, which can more comprehensively determine the required connection points, so as to avoid omission.

In some embodiments of the disclosure, the operationS102 shown in FIG. 1 may be implemented through operations S1021 and S1022, which will be described with reference to the operations.

In an operation S1021, an actual wiring length corresponding to the wiring result topological structure and an expected wiring length corresponding to the expected topological structure are calculated.

In the embodiments of the disclosure, in a process of comparing the wiring result topological structure with the expected topological structure, the wiring quality test apparatus may first calculate the expected wiring length of the expected topological structure and the actual wiring length of the wiring result topological structure.

In an operation S1022, the actual wiring length is compared with the expected wiring length, to obtain the topological structure comparison result.

In the embodiments of the disclosure, the wiring quality test apparatus may compare the actual wiring length with the expected wiring length, to obtain the topological structure comparison result.

It may be understood that the wiring quality test apparatus compares the actual wiring length with the expected wiring length, which facilitates the adjustment of the actual wiring length and appropriately reduces the actual wiring length, thereby reducing the occupation of a processing area, reducing chip sizes, and reducing processing costs.

In some embodiments of the disclosure, the actual wiring length includes a total actual wiring length, and the total actual wiring length is a total length of all actual connection lines in the wiring result topological structure; and the expected wiring length includes a total expected wiring length, and the total expected wiring length is a total length of all expected connection lines in the expected topological structure. The operation S1022 may be implemented through an operation S1023, which will be described with reference to the operations.

In the operation S1023, a ratio of the actual wiring total length to the expected wiring total length is taken as the topological structure comparison result.

In the embodiments of the disclosure, the wiring quality test apparatus may take the ratio of the actual wiring total length to the expected wiring total length as the topological structure comparison result.

In some embodiments of the disclosure, the actual wiring length further includes at least one layer-wise actual wiring length, and the at least one layer-wise actual wiring length is at least one actual connection line length corresponding to at least one metal layer in the wiring result topological structure; and the expected wiring length further includes at least one layer-wise expected wiring length, and the at least one layer-wise expected wiring length is at least one expected connection line length corresponding to the at least one metal layer. The operation S1022 may be implemented through an operation S1024, which will be described with reference to the various operations.

In the operation S1024, each layer-wise actual wiring length in the at least one layer-wise actual wiring length is compared with a respective layer-wise expected wiring length in the at least one layer-wise expected wiring length to obtain at least one metal layer ratio, and the obtained at least one metal layer ratio is taken as the topological structure comparison result.

In the embodiments of the disclosure, the wiring quality test apparatus may compare each layer-wise actual wiring length in the at least one layer-wise actual wiring length with the respective layer-wise expected wiring length in the at least one layer-wise expected wiring length to obtain the at least one metal layer ratio, and take the obtained at least one metal layer ratio as the topological structure comparison result.

It may be understood that the wiring quality test apparatus uses diverse comparison methods such as the total length comparison and the layer-wise length comparison, which can more comprehensively evaluate actual wiring, thereby assisting the designers in optimizing the actual wiring into an optimal solution.

In some embodiments of the disclosure, the operation S105 shown in FIG. 5 may be implemented through operations S1051 and S1053, which will be described with reference to the operations.

In an operation S1051, a selection operation for the set of signals to be tested is received, and a signal to be displayed is determined.

In the embodiments of the disclosure, after generating the quality test report, the wiring quality test apparatus may receive the selection operation of a designer for the set of signals to be tested, to determine the signal to be displayed.

In an operation S1052, a test result corresponding to the signal to be displayed is determined based on the quality test report.

In the embodiments of the disclosure, after determining the signal to be displayed, the wiring quality test apparatus may determine the test result corresponding to the signal to be displayed based on the quality test report. The test result may indicate whether wiring for the signal to be displayed is inappropriate.

In an operation S1053, in response to the test result indicating that wiring for the signal to be displayed is inappropriate, the inappropriate wiring is highlighted on the wiring layout, to complete display of the test result on the wiring layout.

In the embodiments of the disclosure, if the test result indicates that the wiring for the signal to be displayed is inappropriate, the wiring quality test apparatus may emphasize the inappropriate wiring on the wiring layout, for example, highlight the inappropriate wiring, as shown in FIG. 6. In this way, the display of the test result on the wiring layout is completed.

It may be understood that the wiring quality test apparatus receives viewing and selection operations from the designers, highlights inappropriate wiring on the wiring layout, which can assist the designers in modifying and improving the inappropriate wiring, thereby optimizing actual wiring into an optimal solution.

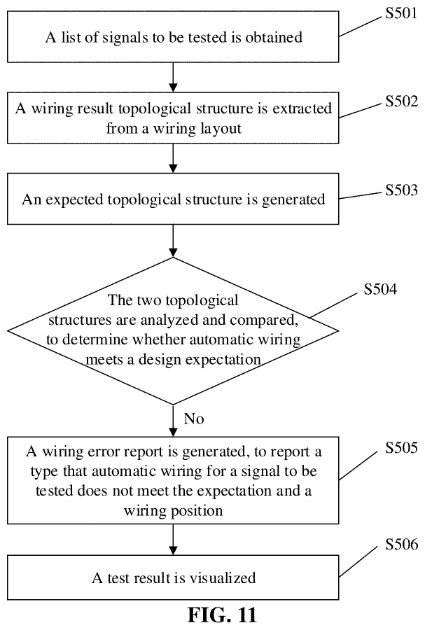

FIG. 11 is an optional schematic flowchart of a wiring quality test method according to an embodiment of the disclosure. The wiring quality test method will be described with reference to operations shown in FIG. 11.

In an operation S501, a list of signals to be tested is obtained.

In the embodiments of the disclosure, a wiring quality test apparatus first obtain the list of signals to be tested. The list of signal to be tested includes all the signals to be tested for which a wiring quality test is required to be performed.

In an operation S502, a wiring result topological structure is extracted from a wiring layout.

In the embodiments of the disclosure, the wiring quality test apparatus may extract the respective wiring result topological structure corresponding to each signal to be tested from the wiring layout.

In an operation S503, an expected topological structure is generated.

In the embodiments of the disclosure, the wiring quality test apparatus generates the respective expected topological structure corresponding to each signal to be tested.

In an operation S504, the two topological structures are analyzed and compared, to determine whether automatic wiring meets a design expectation.

In the embodiments of the disclosure, the wiring quality test apparatus analyzes and compares the two topological structures, to determine whether the automatic wiring meets the expectation.

In an operation S505, a wiring error report is generated, to report a type that automatic wiring for a signal to be tested does not meet the expectation and a wiring position.

In the embodiments of the disclosure, if determining that automatic wiring for a signal to be tested does not meet the design expectation, the wiring quality test apparatus generates the wiring error report for the signal to be tested, to report a type that the automatic wiring for the signal to be tested does not meet the expectation and the wiring position. The type that the automatic wiring does not meet the expectation may include that a total wiring length exceeds a limit and a layer-wise wiring length exceeds a limit.

In an operation S506, a test result is visualized.

In the embodiments of the disclosure, after obtaining the test result including the wiring error report, the wiring quality test apparatus may visualize the test result, to facilitate modification and improvement by the designers.

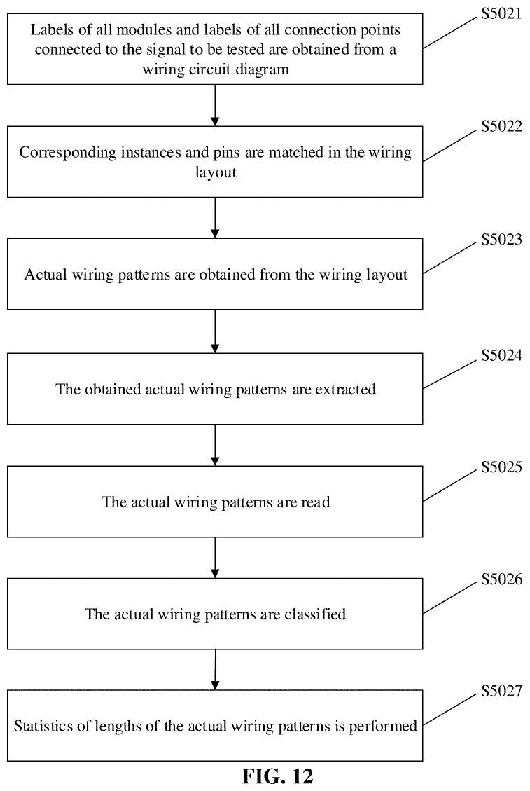

In some embodiments of the disclosure, the operation S502 shown in FIG. 11 may be implemented through operations S5021 to S5027 shown in FIG. 12, which will be described with reference to the operations.

In an operation S5021, labels of all instances (modules) and labels of all pins (connection points) connected to the signal to be tested are obtained from a wiring circuit diagram.

In the embodiments of the disclosure, because a pin or label corresponding to the signal to be tested may be missing in the wiring layout, the wiring quality test apparatus may capture labels of all the instances and pins connected to the specified signal to be tested from the wiring circuit diagram corresponding to the layout. The names of corresponding instances in the wiring circuit diagram and the wiring layout exactly match.

In an operation S5022, corresponding instances and pins are matched in the wiring layout.

In the embodiments of the disclosure, the wiring quality test apparatus may match corresponding instances in the wiring layout to locate pins that are required to be connected.

In an operation S5023, actual wiring patterns are obtained from the wiring layout.

In the embodiments of the disclosure, as shown in FIG. 3B, the wiring quality test apparatus may obtain, from the wiring layout, an actual wiring pattern connected to pins and an actual wiring pattern connected by a Connect (CT) or a via.

In an operation S5024, the obtained actual wiring patterns are extracted.

In the embodiments of the disclosure, as shown in FIG. 3C, the wiring quality test apparatus may extract the obtained actual wiring patterns to facilitate subsequent simplification and calculation.

In an operation S5025, the actual wiring patterns are read.

In the embodiments of the disclosure, the wiring quality test apparatus may read all the actual wiring patterns obtained in the operation S5024.

In an operation S5026, the actual wiring patterns are classified.

In the embodiments of the disclosure, the wiring quality test apparatus may classify the actual wiring patterns.

1. Classification is performed based on metal layers where the actual wiring patterns are located.

2. Classification is performed based on types of the actual wiring patterns. The actual wiring patterns may be classified as a rectangle, a path, and a polygon, and are simplified correspondingly. For a simplification method, reference may be made to FIG. 4A, FIG. 4B, and FIG. 4C.

In an operation S5027, statistics of lengths of the actual wiring patterns is performed.

In the embodiments of the disclosure, the wiring quality test apparatus may use the actual connection lines obtained through simplification in the operation S5026 and the connection points obtained in the operation S5022 to form the wiring result topological structure. In addition, the wiring quality test apparatus may calculate the length of each actual wiring pattern, and gather a total wiring length and layer-wise wiring lengths corresponding to the signal to be tested. In this way, a physical connection calculation result of automatic wiring is obtained. The total wiring length is a length of all actual connection lines corresponding to the signal to be tested; and each layer-wise wiring length is a length of actual connection lines corresponding to each metal layer of different metal layers, which is obtained by adding the actual connection lines corresponding to the metal layer.

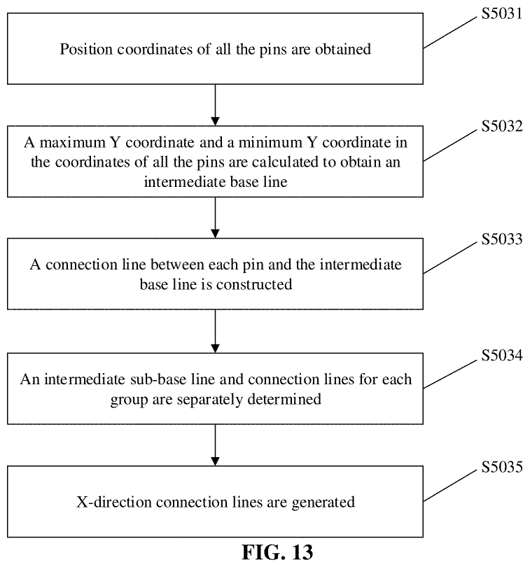

In some embodiments of the disclosure, the operation S503 shown in FIG. 11 may be implemented through operations S5031 to S5035 shown in FIG. 13, which will be described with reference to the operations.

In an operation S5031, position coordinates of all the pins are obtained.

In the embodiments of the disclosure, the wiring quality test apparatus may obtain the position coordinates of all the pins connected to the signal to be tested from the wiring layout. As shown in FIG. 2, I1, I2, I3, I4, I5, I6, and I7 represent instances to be connected to the signal to be tested; and p1, p2, p3, p4, p5, p6, and p7 represent pins to be connected to the signal to be tested, and the position coordinates of all the pins may be obtained.

In an operation S5032, a maximum Y coordinate and a minimum Y coordinate in the coordinates of all the pins are calculated to obtain an intermediate base line.

In the embodiments of the disclosure, the wiring quality test apparatus may calculate the maximum Y coordinate and the minimum Y coordinate in the coordinates of all the pins. As shown in FIG. 2, Y coordinates of p3 and p7 are the maximum Y coordinate and the minimum Y coordinate respectively, which are represented by L1 and L2 respectively. The wiring quality test apparatus may obtain a middle parallel line L3 between L1 and L2. L3 is the intermediate base line.

In an operation S5033, a connection line between each pin and the intermediate base line is constructed.

In the embodiments of the disclosure, the wiring quality test apparatus may construct the connection line between the pin and the intermediate base line, for example, y1 and y2 shown in FIG. 2.

In an operation S5034, an intermediate sub-base line and connection lines for each group are separately determined.

In the embodiments of the disclosure, when position coordinates of a plurality of pins are located within a 150×150 range, these pins form a group. The wiring quality test apparatus may separately calculate the intermediate sub-base line and the connection lines for each group, to better meet the design expectation of the layout. As shown in FIGS. 2, p3 and p4 may form a group, and p5, p6, and p7 may form another group. The wiring quality test apparatus may calculate a maximum Y coordinate and a minimum Y coordinate in coordinates of all pins in each group, to obtain intermediate sub-base lines L6 and L7; and then construct connection lines ys1 and ys2 and connection lines ys3, ys4, and ys5 from the pins in each of two separate groups to the corresponding sub-base line; and finally construct connection lines yb1 and yb2 from the intermediate sub-base lines L6 and L7 to the intermediate base line L3.

In an operation S5035, X-direction connection lines are generated.

In the embodiments of the disclosure, the wiring quality test apparatus finally may generate X-direction connection lines at positions of the intermediate base line and the intermediate sub-base lines, to form the expected topological structure. The expected topological structure may be used for calculating a total expected wiring length as a baseline for comparison.

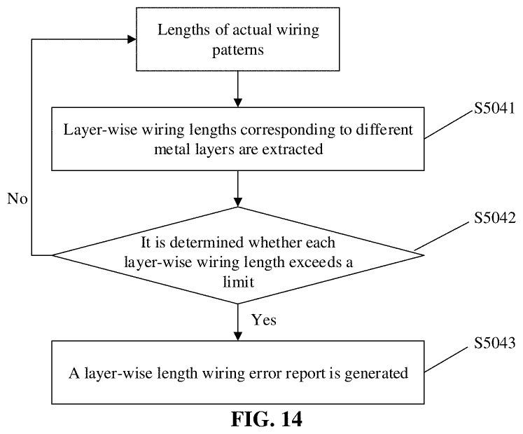

In some embodiments of the disclosure, the operation S504 sown in FIG. 11 may be implemented through operations S5041 to S5043 shown in FIG. 14, which will be described with reference to the operations.

In an operation S5041, layer-wise wiring lengths corresponding to different metal layers are extracted.

In the embodiments of the disclosure, the wiring quality test apparatus may extract the layer-wise wiring lengths corresponding to different metal layers from the lengths of the actual wiring patterns obtained in the operation S5027.

In an operation S5042, it is determined whether each layer-wise wiring length exceeds a limit.

In the embodiments of the disclosure, the wiring quality test apparatus may obtain a limit condition for each metal layer in the quality test, and compare the layer-wise wiring lengths corresponding to different metal layers with the limit conditions to determine whether each layer-wise wiring length exceeds the limit. If the layer-wise wiring length exceeds a limit value, it is determined that the layer-wise wiring length exceeds the limit.

In an operation S5043, a layer-wise length wiring error report is generated.

In the embodiments of the disclosure, if determining that the layer-wise wiring length exceeds the limit, the wiring quality test apparatus generates the layer-wise length wiring error report, to report information such as a signal name and a position of the corresponding metal layer.

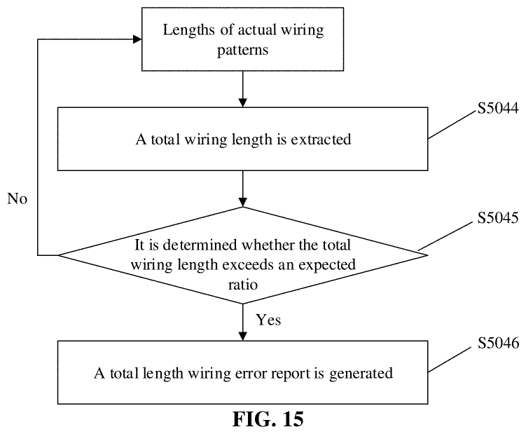

In some embodiments of the disclosure, the operation S504 shown in FIG. 11 may be implemented through operations S5044 to S5046 shown in FIG. 15, which will be described with reference to the operations.

In an operation S5044, a total wiring length is extracted.

In the embodiments of the disclosure, the wiring quality test apparatus may extract the total wiring length of all actual connection lines from the lengths of the actual wiring patterns obtained in the operation S5027.

In an operation S5045, it is determined whether the total wiring length exceeds an expected ratio.

In the embodiments of the disclosure, the wiring quality test apparatus may compare the total wiring length with a limit condition. If a ratio of the total wiring length to the expected value exceeds the limit condition, it is determined that the total wiring length exceeds the expected ratio.

In an operation S5046, a total length wiring error report is generated.

In the embodiments of the disclosure, if determining that the total wiring length exceeds the expected ratio, the wiring quality test apparatus generates the total length wiring error report, to report information such as a signal name and an automatic wiring path.

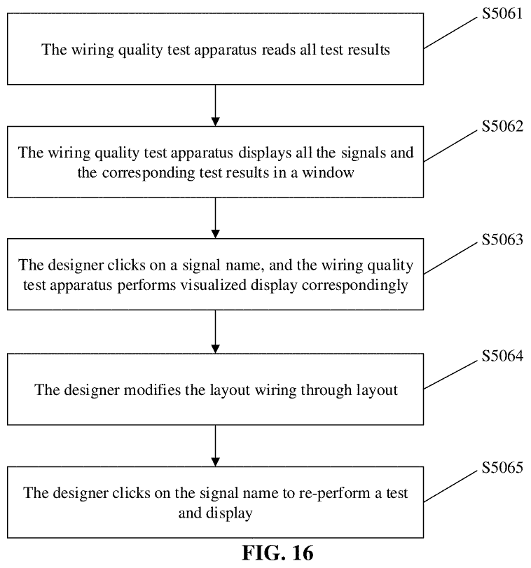

In some embodiments of the disclosure, the operation S506 shown in FIG. 11 may be implemented through operations S5061 to S5065 shown in FIG. 16, which will be described with reference to the operations.

In an operation S5061, the wiring quality test apparatus reads all test results.

In the embodiments of the disclosure, after receiving an instruction of launching a layout from the designer, the wiring quality test apparatus may read all the test results corresponding to the layout.

In an operation S5062, the wiring quality test apparatus displays all the signals and the corresponding test results in a window.

In the embodiments of the disclosure, the wiring quality test apparatus may display all the signals and the corresponding test results in a window for the designer to click and operate.

In an operation S5063, the designer clicks on a signal name, and the wiring quality test apparatus performs visualized display correspondingly.

In the embodiments of the disclosure, the designer may click on the signal name to enable the wiring quality test apparatus to perform visualized display, to assist the designer in modifying and improving the layout. The wiring quality test apparatus may highlight a physical path of inappropriate wiring on the layout, for example, a bold path in FIG. 6. In FIG. 6, direct connection lines between p21, p22, p23, and p24 are not the actual wiring, but instead are used for assisting the designer in locating the positions of connection points.

In an operation S5064, the designer modifies the layout wiring through layout.

In the embodiments of the disclosure, the designer may make a re-layout to the inappropriate wiring to modify and improve the inappropriate wiring.

In an operation S5065, the designer clicks on the signal name to re-perform a test and display.

In the embodiments of the disclosure, after completing modification, the designer may click on the signal name to re-perform the wiring quality test method in the operations S501 to S505. If the signal passes the test, that is, there is no more inappropriate wiring, the wiring quality test apparatus pops up a “Succeed” prompt, and cancels all the highlighting for the signal. If the signal fails to pass the test, that is, there is still inappropriate wiring, the wiring quality test apparatus pops up inappropriate item information of the test result, and highlights the inappropriate wiring for the signal again, to prompt the designer to continue to make modification.

It may be understood that in the wiring quality test method provided in the embodiments of the disclosure, an expected layout topological structure is established, the expected layout topological structure and a layout automatic wiring result are compared and analyzed; if the use of a designated metal layer exceeds a limit or a wiring path is inappropriate, a signal name, a connection relationship, and position information corresponding to the wiring to be modified are reported; and based on a generated test report, the designer is assisted in modifying the signal wiring. In this way, a problem can be discovered in time before a simulation stage, so as to effectively save the time for manual inspection, thereby shortening the development cycle of a project. That is to say, the embodiments of the disclosure achieve the following effects. The quality of automatic wiring of a layout is automatically and efficiently tested, which can discover problems such as that automatic wiring is inappropriate and the use of a designated metal layer exceeds a limit as soon as possible, so as to assist the designers in extraction, modification, and improvement, thereby shortening the development cycle of a chip. A test result of the quality of automatic wiring is visualized, to assist the designer in quick modification and improvement.

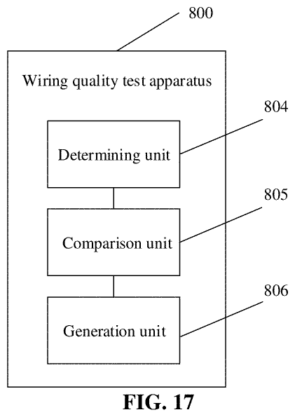

FIG. 17 is an optional schematic structural diagram of a wiring quality test apparatus according to an embodiment of the disclosure. As shown in FIG. 17, the embodiments of the disclosure further provide a wiring quality test apparatus 800, including a determining unit 804, a comparison unit 805, and a generation unit 806.

The determining unit 804 is configured to determine a respective wiring result topological structure and a respective expected topological structure corresponding to each signal to be tested in a set of signals to be tested based on a wiring layout, where the expected topological structure is obtained based on a position of at least one connection point in the wiring layout.

The comparison unit 805 is configured to: for each signal to be tested, compare the wiring result topological structure with the expected topological structure, to obtain a topological structure comparison result corresponding to the signal to be tested.

The determining unit 804 is further configured to: if the topological structure comparison result is greater than a preset threshold, determine a test result indicating that wiring for the signal to be tested is inappropriate.

The generation unit 806 is configured to generate a quality test report based on test results of the signals to be tested.

In some embodiments of the disclosure, the wiring quality test apparatus 800 further includes a display unit 807.

The display unit 807 is configured to display the test result on the wiring layout based on the quality test report.

In some embodiments of the disclosure, the wiring quality test apparatus 800 further includes an obtaining unit 808.

The obtaining unit 808 is configured to obtain a wiring circuit diagram corresponding to the wiring layout.

The determining unit 804 is further configured to: determine the at least one connection point corresponding to each signal to be tested based on the wiring layout and the wiring circuit diagram; determine the respective expected topological structure corresponding to each signal to be tested in the set of signals to be tested from the wiring layout based on the at least one connection point corresponding to each signal to be tested; and determine the respective wiring result topological structure corresponding to each signal to be tested in the set of signals to be tested from the wiring layout based on the at least one connection point corresponding to each signal to be tested.

In some embodiments of the disclosure, the determining unit 804 is further configured to: in the wiring layout, take the at least one connection point corresponding to each signal to be tested as at least one first-level connection point, and determine a first-level intermediate base line based on the at least one first-level connection point; determine connection points having an axial distance less than an i^{th}-level preset threshold in (i−1)^{th}-level connection points as i^{th}-level connection points, and determine an i^{th}-level intermediate base line based on the i^{th}-level connection points, where i is greater than or equal to 2 and i is less than or equal to N−1, the axial distance is a distance in a first axial direction or a second axial direction, and the first axial direction is perpendicular to the second axial direction; continue to determine (i+1)^{th}-level connection points and an (i+1)^{th}-level intermediate base line until N^{th}-level connection points and an N^{th}-level intermediate base line are determined; determine an expected connection line of each level based on connection points of each level and an intermediate base line of each level in the connection points of N levels and intermediate base lines of N levels, thereby determining expected connection lines of N levels; and use the at least one connection point and the expected connection lines of N levels to form the respective expected topological structure corresponding to each signal to be tested in the set of signals to be tested.

In some embodiments of the disclosure, the determining unit 804 is further configured to: determine an N^{th}-level expected connection line based on the N^{th}-level connection points and the N^{th}-level intermediate base line; determine a j^{th}-level expected connection line based on j^{th}-level connection points, a j^{th}-level intermediate base line, and a (j+1)^{th}-level expected connection line, where j is greater than or equal to 2 and j is less than or equal to N−1; and continue to determine a (j−1)^{th}-level expected connection line until a first-level expected connection line is determined, thereby determining the expected connection lines of N levels.

In some embodiments of the disclosure, the determining unit 804 is further configured to: determine two first-level edge connection points having a largest distance in the first axial direction among the at least one first-level connection point; and determine the first-level intermediate base line passing through a midpoint of a connection line between the two first-level edge connection points and in the second axial direction.

In some embodiments of the disclosure, the determining unit 804 is further configured to: determine two i^{th}-level edge connection points having a largest distance in the first axial direction among the i^{th}-level connection points; and determine the i^{th}-level intermediate base line passing through a midpoint of a connection line between the two i^{th}-level edge connection points and in the second axial direction.

In some embodiments of the disclosure, the determining unit 804 is further configured to: for a first connection point that does not satisfy a preset distance condition in the connection points of each level in the connection points of N levels, connect the first connection point of each level to the intermediate base line of the level corresponding to the first connection point to form a perpendicular segment, so as to obtain a first sub-expected connection line corresponding to the first connection point; for a second connection point that satisfies the preset distance condition in the connection points of each level in the connection points of N levels, connect the intermediate base line of each level corresponding to the second connection point of the level to the intermediate base line of a next level to form a common perpendicular segment, so as to obtain a second sub-expected connection line corresponding to the second connection point, where the first sub-expected connection line and the second sub-expected connection line are taken as the expected connection lines of each level; and until the connection points of N levels have been connected, determine the expected connection lines of N levels.

In some embodiments of the disclosure, the determining unit 804 is further configured to: determine at least one actual wiring pattern connected to the at least one connection point in the wiring layout; determine a type of each actual wiring pattern in the at least one actual wiring pattern, and correspondingly simplify each actual wiring pattern, to obtain at least one actual connection line corresponding to the at least one actual wiring pattern; and use the at least one connection point and the at least one actual connection line to form the respective wiring result topological structure corresponding to each signal to be tested in the set of signals to be tested.

In some embodiments of the disclosure, the determining unit 804 is further configured to: determine that each actual wiring pattern is one of a rectangle, a path, and a polygon; and if the actual wiring pattern is a rectangle, take a perpendicular bisector of a short side of the rectangle in the actual wiring pattern as at least one actual connection line corresponding to the actual wiring pattern; or if the actual wiring pattern is a path, connect center points in axial directions of the path in the actual wiring pattern to form at least one actual connection line corresponding to the actual wiring pattern; or if the actual wiring pattern is a polygon, which represents that the actual wiring pattern and a layer via are connected at a layer via connection line, take a perpendicular bisector of the layer via connection line in the actual wiring pattern as at least one actual connection line corresponding to the actual wiring pattern, thereby obtaining the at least one actual connection line corresponding to the at least one actual wiring pattern.

In some embodiments of the disclosure, the obtaining unit 808 is further configured to: obtain at least one connection object label corresponding to each signal to be tested from the wiring circuit diagram; and match at least one connection object corresponding to the at least one connection object label in the wiring layout.

The determining unit 804 is further configured to: determine the at least one connection point corresponding to each signal to be tested based on the at least one connection object in the wiring layout.

In some embodiments of the disclosure, the wiring quality test apparatus 800 further includes a calculation unit 809.

The calculation unit 809 is configured to calculate an actual wiring length corresponding to the wiring result topological structure and an expected wiring length corresponding to the expected topological structure.

The comparison unit 805 is further configured to compare the actual wiring length with the expected wiring length, to obtain the topological structure comparison result.

In some embodiments of the disclosure, the actual wiring length includes a total actual wiring length, the total actual wiring length being a total length of all actual connection lines in the wiring result topological structure; and the expected wiring length includes a total expected wiring length, the total expected wiring length being a total length of all expected connection lines in the expected topological structure. The comparison unit 805 is further configured to take a ratio of the total actual wiring length to the total expected wiring length as the topological structure comparison result.

In some embodiments of the disclosure, the actual wiring length further includes at least one layer-wise actual wiring length, the at least one layer-wise actual wiring length being at least one actual connection line length corresponding to at least one metal layer in the wiring result topological structure; and the expected wiring length further includes at least one layer-wise expected wiring length, the at least one layer-wise expected wiring length being at least one expected connection line length corresponding to the at least one metal layer. The comparison unit 805 is further configured to compare each layer-wise actual wiring length in the at least one layer-wise actual wiring length with a respective layer-wise expected wiring length in the at least one layer-wise expected wiring length to obtain at least one metal layer ratio, and take the obtained at least one metal layer ratio as the topological structure comparison result.

In some embodiments of the disclosure, the determining unit 804 is further configured to: receive a selection operation for the set of signals to be tested, and determine a signal to be displayed; and determine a test result corresponding to the signal to be displayed based on the quality test report.

The display unit 807 is further configured to: if the test result indicates that wiring for the signal to be displayed is inappropriate, highlight the inappropriate wiring on the wiring layout, thereby completing display of the test result on the wiring layout.

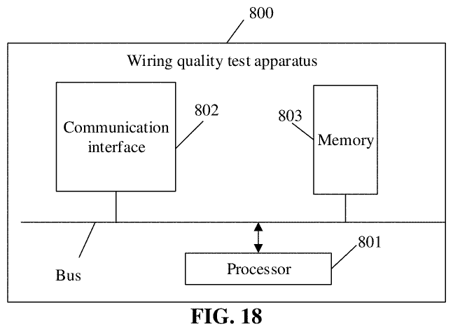

It should be noted that FIG. 18 is an optional schematic structural diagram of a wiring quality test apparatus according to an embodiment of the disclosure. As shown in FIG. 18, the hardware entities of the wiring quality test apparatus 800 include a processor 801, a communication interface 802, and a memory 803.

The processor 801 is configured to control the overall operations of wiring quality test apparatus 800.

The communication interface 802 is configured to enable the wiring quality test apparatus 800 to communicate with another apparatus or device through a network.

The memory 803 is configured to store instructions and applications executable by the processor 801, or cache data (for example, image data, audio data, voice communication data, and video communication data) to be processed or already processed by the processor 801 and the modules in the wiring quality test apparatus 800. The memory can be implemented as a flash memory (FLASH) or a Random Access Memory (RAM).

It should be noted that in the embodiments of the disclosure, when the aforementioned wiring quality test method is implemented in the form of a software functional module and sold or used as an independent product, the method may be stored in a computer-readable storage medium. Based on such an understanding, the technical solutions in the embodiments of the disclosure essentially, or the part contributing to some implementations may be implemented in the form of a software product. The computer software product is stored in a storage medium, including several instructions for instructing the wiring quality test apparatus 800 (which may be a personal computer, a server, a network device or the like) to perform all or part of the operations of the methods described in the embodiments of the disclosure. The foregoing storage medium includes various media that can store program codes, such as a Universal Serial Bus (USB) flash drive, a removable hard disk, a Read-Only Memory (ROM), a magnetic disk or an optical disc. In this way, the embodiments of the disclosure are not limited to any specific combination of hardware and software.

Correspondingly, the embodiments of the disclosure provide a computer-readable storage medium storing thereon a computer program that, when executed by a processor, causes the processor to perform the operations in the method corresponding to the aforementioned wiring quality test apparatus.

It should be noted herein that the above description of the embodiments of the storage medium and device is similar to the description of the method embodiments above, and has beneficial effects similar to those of the method embodiments. For technical details not disclosed in the embodiments of the storage medium and device of the disclosure, the reference may be made to the description of the method embodiments of the disclosure for comprehension.

It should be noted that the terms “include”, “comprise”, or any variation thereof herein are intended to cover a non-exclusive inclusion. Therefore, a process, method, article or apparatus including a series of elements includes not only such elements, but also includes other elements not specified expressly, or may include elements inherent to the process, method, object or apparatus. Without further limitation, an element defined by the phrase “include/comprise a/an . . . ” does not exclude the presence of other same elements in the process, the method, the object or the apparatus including the element.

In several embodiments provided in the disclosure, it should be understood that the disclosed devices and methods may be implemented in other forms. The described device embodiments are merely examples. For example, the unit division is merely logical function division and may be other division in actual implementation. For example, a plurality of units or components may be combined or integrated into another system, or some features may be ignored or not performed. In addition, mutual couplings or direct couplings or communication connections between the shown or discussed components may be indirect couplings or communication connections through some interfaces, devices or units, and may be electrical, mechanical, or adopt other forms.

The units described as separate components may or may not be physically separate, and components shown as units may or may not be physical units, that is, may be located in one position, or may be distributed on a plurality of network units. Some or all of the units may be selected according to actual needs to achieve the purpose of the solutions in the embodiments.

In addition, functional units in the embodiments of the disclosure may all be integrated into one processing unit, or each of the units may exist alone, or two or more units are integrated into one unit. The integrated unit may be implemented in the form of hardware or hardware combined with software functional units.

The foregoing descriptions are merely implementations of the disclosure, but are not intended to limit the protection scope of the disclosure. Any variation or replacement that may be readily conceived by a person skilled in the art within the technical scope disclosed in the disclosure shall fall within the protection scope of the disclosure. Therefore, the protection scope of the disclosure shall be subject to the protection scope of the claims.

The embodiments of the disclosure provide a wiring quality test method and apparatus and a storage medium. A respective wiring result topological structure and a respective expected topological structure corresponding to each signal to be tested in a set of signals to be tested are determined based on a wiring layout. For each signal to be tested, the wiring result topological structure is compared with the expected topological structure, to obtain a topological structure comparison result corresponding to the signal to be tested. In response to determining that the topological structure comparison result is greater than a preset threshold, it is determined a test result indicating that wiring for the signal to be tested is inappropriate. A quality test report is generated based on test results of the signals to be tested. In this way, results of automatic wiring are tested by running procedures without search and verification one by one by designers, so that the test of wiring quality is quickly completed, thereby implementing the automatic test of wiring quality and saving the test time.

What is claimed is:

1. A wiring quality test method, comprising:
determining, based on a wiring layout, a respective wiring result topological structure and a respective expected topological structure corresponding to each signal to be tested in a set of signals to be tested, wherein the expected topological structure is obtained based on a position of at least one connection point in the wiring layout;
for each signal to be tested, comparing the wiring result topological structure with the expected topological structure, to obtain a topological structure comparison result corresponding to the signal to be tested;
in response to determining that the topological structure comparison result is greater than a preset threshold, determining a test result indicating that wiring for the signal to be tested is inappropriate; and
generating a quality test report based on test results of the signals to be tested.

2. The wiring quality test method according to claim 1, wherein determining, based on the wiring layout, the respective wiring result topological structure and the respective expected topological structure corresponding to each signal to be tested in the set of signals to be tested comprises:
obtaining a wiring circuit diagram corresponding to the wiring layout;
determining the at least one connection point corresponding to each signal to be tested based on the wiring layout and the wiring circuit diagram;
determining the respective expected topological structure corresponding to each signal to be tested in the set of signals to be tested from the wiring layout based on the at least one connection point corresponding to each signal to be tested; and
determining the respective wiring result topological structure corresponding to each signal to be tested in the set of signals to be tested from the wiring layout based on the at least one connection point corresponding to each signal to be tested.

3. The wiring quality test method according to claim 2, wherein the at least one connection point comprises connection points of N levels, N being greater than or equal to 1; and
wherein determining the respective expected topological structure corresponding to each signal to be tested in the set of signals to be tested from the wiring layout based on the at least one connection point corresponding to each signal to be tested comprises:
in the wiring layout, taking the at least one connection point corresponding to each signal to be tested as at least one first-level connection point, and determining a first-level intermediate base line based on the at least one first-level connection point;
determining connection points having an axial distance less than an i^{th}-level preset threshold in (i−1)^{th}-level connection points as i^{th}-level connection points, and determining an i^{th}-level intermediate base line based on the i^{th}-level connection points, wherein i is greater than or equal to 2 and less than or equal to N−1, the axial distance is a distance in a first axial direction or a second axial direction, and the first axial direction is perpendicular to the second axial direction;
continuing to determine (i+1)^{th}-level connection points and an (i+1)^{th}-level intermediate base line until N^{th}-level connection points and an N^{th}-level intermediate base line are determined;
determining an expected connection line of each level based on connection points of each level and an intermediate base line of each level in the connection points of N levels and intermediate base lines of N levels, thereby determining expected connection lines of N levels; and
using the at least one connection point and the expected connection lines of N levels to form the respective expected topological structure corresponding to each signal to be tested in the set of signals to be tested.

4. The wiring quality test method according to claim 3, wherein determining the expected connection line of each level based on the connection points of each level and the intermediate base line of each level in the connection points of N levels and the intermediate base lines of N levels, thereby determining the expected connection lines of N levels comprises:
determining an N^{th}-level expected connection line based on the N^{th}-level connection points and the N^{th}-level intermediate base line;
determining a j^{th}-level expected connection line based on j^{th}-level connection points, a j^{th}-level intermediate base line, and a (j+1)^{th}-level expected connection line, wherein j is greater than or equal to 2 and less than or equal to N−1; and
continuing to determine a (j−1)^{th}-level expected connection line until a first-level expected connection line is determined, thereby determining the expected connection lines of N levels.

5. The wiring quality test method according to claim 3, wherein determining the first-level intermediate base line based on the at least one first-level connection point comprises:
determining two first-level edge connection points having a largest distance in the first axial direction among the at least one first-level connection point; and
determining the first-level intermediate base line passing through a midpoint of a connection line between the two first-level edge connection points and in the second axial direction.

6. The wiring quality test method according to claim 5, wherein determining the i^{th}-level intermediate base line based on the i^{th}-level connection points comprises:
determining two i^{th}-level edge connection points having a largest distance in the first axial direction among the i^{th}-level connection points; and
determining the i^{th}-level intermediate base line passing through a midpoint of a connection line between the two i^{th}-level edge connection points and in the second axial direction.

7. The wiring quality test method according to claim 3, wherein determining the expected connection line of each level based on the connection points of each level and the intermediate base line of each level in the connection points of N levels and the intermediate base lines of N levels, thereby determining the expected connection lines of N levels comprises:
for a first connection point that does not satisfy a preset distance condition in the connection points of each level in the connection points of N levels, connecting the first connection point of each level to the intermediate base line of the level corresponding to the first connection point to form a perpendicular segment, so as to obtain a first sub-expected connection line corresponding to the first connection point;
for a second connection point that satisfies the preset distance condition in the connection points of each level in the connection points of N levels, connecting the intermediate base line of each level corresponding to the second connection point of the level to the intermediate reference line of a next level to form a common perpendicular segment, so as to obtain a second sub-expected connection line corresponding to the second connection point,
wherein the first sub-expected connection line and the second sub-expected connection line are taken as the expected connection line of each level; and
until the connection points of N levels have been connected, determining the expected connection lines of N levels.

8. The wiring quality test method according to claim 2, wherein determining the respective wiring result topological structure corresponding to each signal to be tested in the set of signals to be tested from the wiring layout based on the at least one connection point corresponding to each signal to be tested comprises:
determining at least one actual wiring pattern connected to the at least one connection point in the wiring layout;
determining a type of each actual wiring pattern in the at least one actual wiring pattern, and simplifying each actual wiring pattern, to obtain at least one actual connection line corresponding to the at least one actual wiring pattern; and
using the at least one connection point and the at least one actual connection line to form the respective wiring result topological structure corresponding to each signal to be tested in the set of signals to be tested.

9. The wiring quality test method according to claim 8, wherein determining the type of each actual wiring pattern in the at least one actual wiring pattern, and simplifying each actual wiring pattern, to obtain the at least one actual connection line corresponding to the at least one actual wiring pattern comprises:
determining that each actual wiring pattern is one of a rectangle, a path, and a polygon; and
in response to determining that the actual wiring pattern is a rectangle, taking a perpendicular bisector of a short side of the rectangle in the actual wiring pattern as at least one actual connection line corresponding to the actual wiring pattern; or
in response to determining that the actual wiring pattern is a path, connecting center points in axial directions of the path in the actual wiring pattern to form at least one actual connection line corresponding to the actual wiring pattern; or
in response to determining that the actual wiring pattern is a polygon, which represents that the actual wiring pattern and a layer via are connected at a layer via connection line, taking a perpendicular bisector of the layer via connection line in the actual wiring pattern as at least one actual connection line corresponding to the actual wiring pattern,
thereby obtaining the at least one actual connection line corresponding to the at least one actual wiring pattern.

10. The wiring quality test method according to claim 2, wherein determining the at least one connection point corresponding to each signal to be tested based on the wiring layout and the wiring circuit diagram comprises:
obtaining, in the wiring circuit diagram, at least one connection object label corresponding to each signal to be tested;
matching, in the wiring layout, at least one connection object corresponding to the at least one connection object label; and
determining the at least one connection point corresponding to each signal to be tested based on the at least one connection object in the wiring layout.

11. The wiring quality test method according to claim 1, wherein for each signal to be tested, comparing the wiring result topological structure with the expected topological structure, to obtain the topological structure comparison result corresponding to the signal to be tested comprises:
calculating an actual wiring length corresponding to the wiring result topological structure and an expected wiring length corresponding to the expected topological structure; and
comparing the actual wiring length with the expected wiring length, to obtain the topological structure comparison result.

12. The wiring quality test method according to claim 11, wherein the actual wiring length comprises a total actual wiring length, the total actual wiring length being a total length of all actual connection lines in the wiring result topological structure; and the expected wiring length comprises a total expected wiring length, the total expected wiring length being a total length of all expected connection lines in the expected topological structure; and
wherein comparing the actual wiring length with the expected wiring length, to obtain the topological structure comparison result comprises:
taking a ratio of the total actual wiring length to the total expected wiring length as the topological structure comparison result.

13. The wiring quality test method according to claim 11, wherein the actual wiring length comprises at least one layer-wise actual wiring length, the at least one layer-wise actual wiring length being at least one actual connection line length corresponding to at least one metal layer in the wiring result topological structure; and the expected wiring length comprises at least one layer-wise expected wiring length, the at least one layer-wise expected wiring length being at least one expected connection line length corresponding to the at least one metal layer; and
wherein comparing the actual wiring length with the expected wiring length, to obtain the topological structure comparison result comprises:
comparing each layer-wise actual wiring length in the at least one layer-wise actual wiring length with a respective layer-wise expected wiring length in the at least one layer-wise expected wiring length to obtain at least one metal layer ratio, and taking the at least one metal layer ratio as the topological structure comparison result.

14. The wiring quality test method according to claim 1, further comprising: after generating the quality test report based on the test results of the signals to be tested,
displaying the test result on the wiring layout based on the quality test report.

15. The wiring quality test method according to claim 14, wherein displaying the test result on the wiring layout based on the quality test report comprises:
receiving a selection operation for the set of signals to be tested, and determining a signal to be displayed;
determining a test result corresponding to the signal to be displayed based on the quality test report; and
in response to the test result indicating that wiring for the signal to be displayed is inappropriate, highlighting the inappropriate wiring on the wiring layout, thereby completing display of the test result on the wiring layout.

16. A wiring quality test apparatus, comprising:
a memory, configured to store executable instructions; and
a processor, configured to execute the executable instructions stored in the memory to perform the following operations comprising:
determining, based on a wiring layout, a respective wiring result topological structure and a respective expected topological structure corresponding to each signal to be tested in a set of signals to be tested, wherein the expected topological structure is obtained based on a position of at least one connection point in the wiring layout;
for each signal to be tested, comparing the wiring result topological structure with the expected topological structure, to obtain a topological structure comparison result corresponding to the signal to be tested;
in response to determining that the topological structure comparison result is greater than a preset threshold, determining a test result indicating that wiring for the signal to be tested is inappropriate; and
generating a quality test report based on test results of the signals to be tested.

17. The wiring quality test apparatus according to claim 16, wherein the processor is configured to:
obtain a wiring circuit diagram corresponding to the wiring layout;
determine the at least one connection point corresponding to each signal to be tested based on the wiring layout and the wiring circuit diagram;
determine the respective expected topological structure corresponding to each signal to be tested in the set of signals to be tested from the wiring layout based on the at least one connection point corresponding to each signal to be tested; and
determine the respective wiring result topological structure corresponding to each signal to be tested in the set of signals to be tested from the wiring layout based on the at least one connection point corresponding to each signal to be tested.

18. The wiring quality test apparatus according to claim 17, wherein the at least one connection point comprises connection points of N levels, N being greater than or equal to 1; and the processor is configured to:
in the wiring layout, take the at least one connection point corresponding to each signal to be tested as at least one first-level connection point, and determine a first-level intermediate base line based on the at least one first-level connection point;
determine connection points having an axial distance less than an ith-level preset threshold in (i−1)th-level connection points as ith-level connection points, and determine an ith-level intermediate base line based on the ith-level connection points, wherein i is greater than or equal to 2 and less than or equal to N−1, the axial distance is a distance in a first axial direction or a second axial direction, and the first axial direction is perpendicular to the second axial direction;
continue to determine (i+1)th-level connection points and an (i+1)th-level intermediate base line until Nth-level connection points and an Nth-level intermediate base line are determined;
determine an expected connection line of each level based on connection points of each level and an intermediate base line of each level in the connection points of N levels and intermediate base lines of N levels, thereby determining expected connection lines of N levels; and
use the at least one connection point and the expected connection lines of N levels to form the respective expected topological structure corresponding to each signal to be tested in the set of signals to be tested.

19. The wiring quality test apparatus according to claim 18, wherein the processor is configured to:
determine an N^{th}-level expected connection line based on the N^{th}-level connection points and the N^{th}-level intermediate base line;
determine a j^{th}-level expected connection line based on j^{th}-level connection points, a j^{th}-level intermediate base line, and a (j+1)^{th}-level expected connection line, wherein j is greater than or equal to 2 and less than or equal to N−1; and
continue to determine a (j−1)^{th}-level expected connection line until a first-level expected connection line is determined, thereby determining the expected connection lines of N levels.

20. A non-transitory computer-readable storage medium, storing executable instructions that, when being executed by a processor, cause the processor to perform a wiring quality test method comprising:
determining, based on a wiring layout, a respective wiring result topological structure and a respective expected topological structure corresponding to each signal to be tested in a set of signals to be tested, wherein the expected topological structure is obtained based on a position of at least one connection point in the wiring layout;
for each signal to be tested, comparing the wiring result topological structure with the expected topological structure, to obtain a topological structure comparison result corresponding to the signal to be tested;
in response to determining that the topological structure comparison result is greater than a preset threshold, determining a test result indicating that wiring for the signal to be tested is inappropriate; and
generating a quality test report based on test results of the signals to be tested.
